(19) United States
(12) Patent Application Publication
(10) Pub. No.: US 2026/0047196 A1
(43) Pub. Date: Feb. 12, 2026

(54) SEMICONDUCTOR DEVICE AND MANUFACTURING METHOD THEREOF

(71) Applicant: Taiwan Semiconductor Manufacturing Company, Ltd., Hsinchu (TW)

(72) Inventors: Yuan-Chang CHEN, Miaoli County (TW); Po-Yu HUANG, Hsinchu (TW); Mei-Yun WANG, Hsinchu Country (TW); Chen-Ming LEE, Taoyuan City (TW); I-Wen WU, Hsinchu City (TW); Shih-Chieh WU, Hsinchu (TW)

(73) Assignee: Taiwan Semiconductor Manufacturing Company, Ltd., Hsinchu (TW)

(21) Appl. No.: 18/795,810

(22) Filed: Aug. 6, 2024

(51) Int. Cl. H01L 27/092; H01L 21/283; H01L 21/8238; H01L 29/06; H01L 29/423; H01L 29/66; H01L 29/775; H01L 29/786

(52) U.S. Cl. CPC H10D 84/856; H10D 62/021; H10D 62/116; H10D 84/017; H10D 84/038; H01L 21/283; H10D 30/014; H10D 30/43; H10D 30/6735; H10D 30/6757; H10D 62/121

(57) ABSTRACT

A method includes forming a plurality of channel layers vertically stacked over a semiconductor substrate; forming a gate structure surrounding the channel layers; forming a first source/drain epitaxial structure on a first side of the channel layers; etching a first opening at least in the semiconductor substrate and the first source/drain epitaxial structure expose a backside of the first source/drain epitaxial structure; and forming an isolation plug in the first opening, wherein the isolation plug is at least laterally aligned with a bottommost one of the channel layers.

### BACKGROUND

Semiconductor integrated circuit (IC) industry has experienced rapid growth. Technological advances in IC materials and design have produced generations of ICs where each generation has smaller and more complex circuits than the previous generation. However, these advances have increased the complexity of processing and manufacturing ICs and, for these advances to be realized, similar developments in IC processing and manufacturing are needed.

In the course of IC evolution, functional density (i.e., the number of interconnected devices per chip area) has generally increased while geometry size (i.e., the smallest component (or line) that can be created using a fabrication process) has decreased. This scaling down process generally provides benefits by increasing production efficiency and lowering associated costs. Such scaling-down also produces a relatively high power dissipation value, which may be addressed by using low power dissipation devices such as complementary metal-oxide-semiconductor (CMOS) devices.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1-17 illustrate schematic and cross-sectional views of intermediate stages in the manufacture of a semiconductor device in accordance with some embodiments of the present disclosure.

FIGS. 18-23 illustrate cross-sectional views of intermediate stages in the manufacture of a semiconductor device in accordance with some embodiments of the present disclosure.

FIGS. 24-33 illustrate cross-sectional views of intermediate stages in the manufacture of a semiconductor device in accordance with some embodiments of the present disclosure.

FIG. 34 is a cross-sectional view of a semiconductor device in accordance with some embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

As used herein, “around,” “about,” “approximately,” or “substantially” may mean within 20 percent, or within 10 percent, or within 5 percent of a given value or range. One skilled in the art will realize, however, that the value or range recited throughout the description are merely examples, and may be reduced with the down-scaling of the integrated circuits. Numerical quantities given herein are approximate, meaning that the term “around,” “about,” “approximately,” or “substantially” can be inferred if not expressly stated.

The gate all around (GAA) transistor structures may be patterned by any suitable method. For example, the structures may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in some embodiments, a sacrificial layer is formed over a substrate and patterned using a photolithography process. Spacers are formed alongside the patterned sacrificial layer using a self-aligned process. The sacrificial layer is then removed, and the remaining spacers may then be used to pattern the GAA structure.

In some embodiments of the present disclosure, a depth control backside process is developed to achieve flexible number of nanosheets in multi-gate devices. The number of nanosheets are factors to device performance, device speed, and device power consumption. The term “multi-gate device” is used to describe a device (e.g., a semiconductor transistor) that has at least some gate material disposed on multiple sides of at least one channel of the device. In some examples, the multi-gate device may be referred to as a GAA device or a nanosheet device having gate material disposed on at least four sides of at least one channel of the device. The channel region may be referred to as a “nanowire,” which as used herein includes channel regions of various geometries (e.g., cylindrical, bar-shaped) and various dimensions. In some examples, the multi-gate device may be referred to as a FinFET device. However, one of ordinary skill would recognize that the teaching can apply to a single channel (e.g., single nanosheet) or any number of channels. One of ordinary skill may recognize other examples of semiconductor devices that may benefit from aspects of the present disclosure.

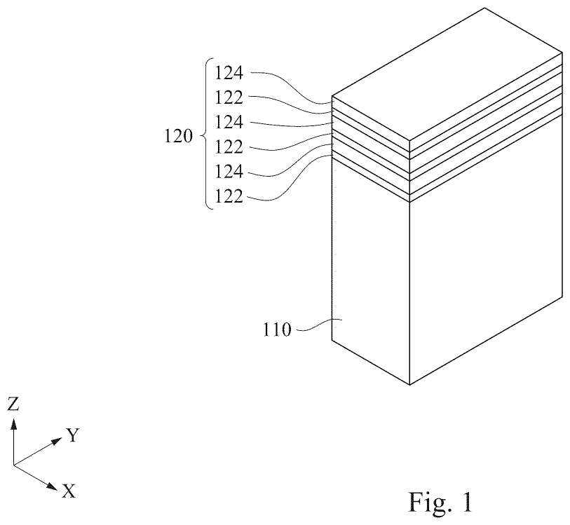

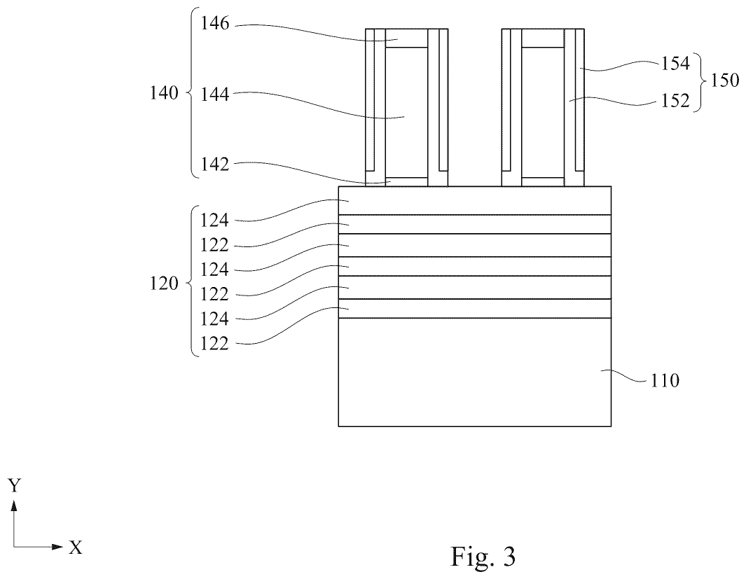

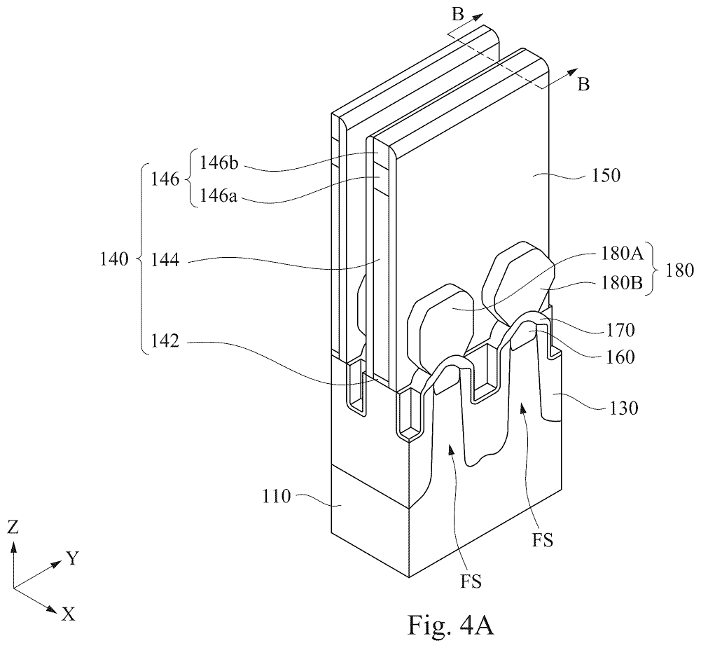

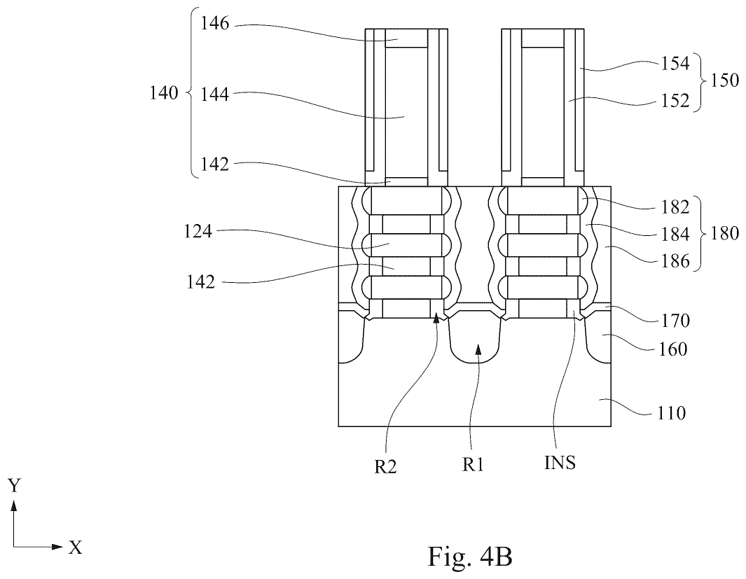

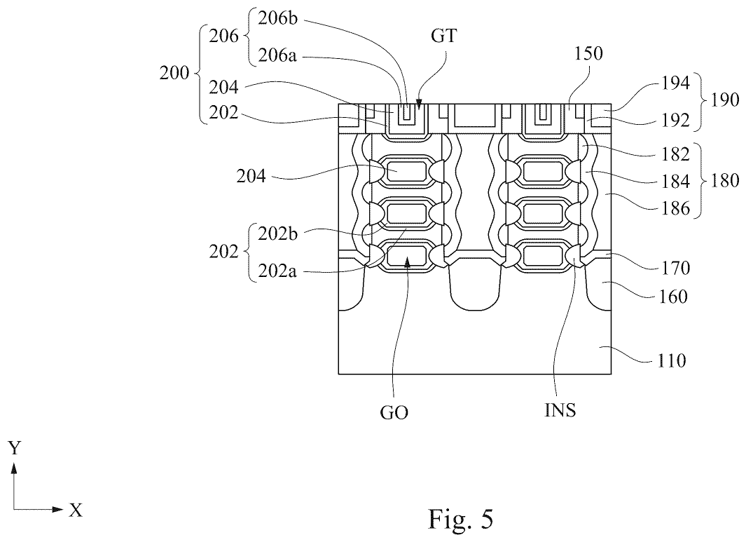

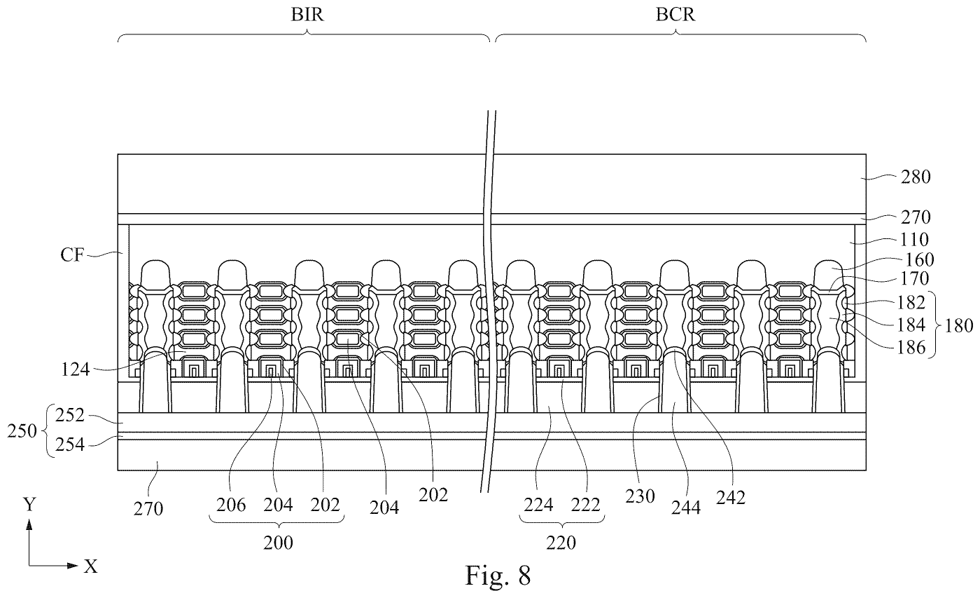

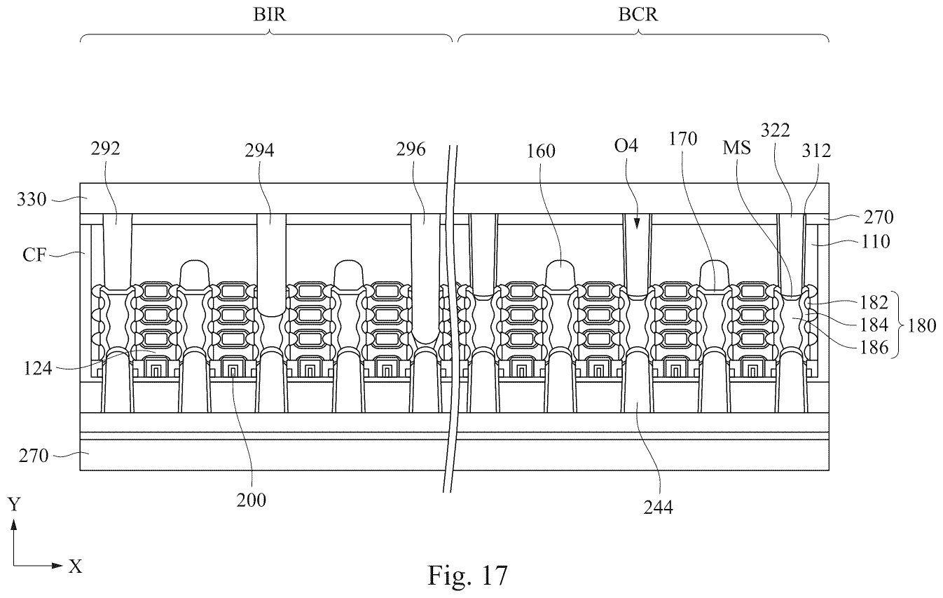

FIGS. 1-17 illustrate schematic and cross-sectional views of intermediate stages in the manufacture of a semiconductor device in accordance with some embodiments of the present disclosure. FIGS. 1, 2, 4A, 6, and 7 are schematic views of the semiconductor device at various manufacturing stages in accordance with some embodiments. FIG. 4B is a cross-sectional view of the semiconductor device taken along line B-B in FIG. 4A at various manufacturing stages in accordance with some embodiments. FIGS. 3 and 5 are cross-sectional views of the semiconductor device taken along a same direction as the line B-B in FIG. 4A at various manufacturing stages in accordance with some embodiments. FIGS. 8-17 illustrates cross-sectional views of various regions of the semiconductor device taken along a same direction as the line B-B in FIG. 4A at various manufacturing stages in accordance with some embodiments. The illustrated process in FIGS. 1-17 may be applicable to manufacture the semiconductor device in FIG. 17. It is understood that additional steps may be provided before, during, and after the steps shown in FIGS. 1-17, and some of the steps described below can be replaced or eliminated for additional embodiments of the method. The order of the operations/processes may be interchangeable.

Reference is made to FIG. 1. An epitaxial stack 120 is formed over a substrate 110. In some embodiments, the substrate 110 may include silicon (Si). Alternatively, the substrate 110 may include germanium (Ge), silicon germanium (SiGe), a III-V material (e.g., GaAs, GaP, GaAsP, AlInAs, AlGaAs, GalnAs, InAs, GaInP, InP, InSb, and/or GaInAsP; or a combination thereof) or other appropriate semiconductor materials. In some embodiments, the substrate 110 may include a semiconductor-on-insulator (SOI) structure such as a buried dielectric layer. Also, the substrate 110 may include a buried dielectric layer such as a buried oxide (BOX) layer, such as that formed by a method referred to as separation by implantation of oxygen (SIMOX) technology, wafer bonding, selective epitaxial growth (SEG), or another appropriate method.

The epitaxial stack 120 includes sacrificial layers 122 interposed by channel layers 124. The sacrificial layers 122 and the channel layers 124 may have different semiconductor compositions from each other. In some embodiments, the sacrificial layers 122 and the channel layers 124 may include SiGe with different semiconductor compositions. For example, a Si concentration in the sacrificial layers 122 is less than a Si concentration in the channel layers 124. Stated differently, in the embodiments, a Ge concentration in the sacrificial layers 122 is greater than a Ge concentration in the channel layers 124. For example, the sacrificial layers 122 are SiₓGe₁₋ₓ, and the channel layers 124 are Si_{y}Ge_{1-y}, in which x and y are in a range from 0 to 1, and y>x. However, other embodiments are possible including those that provide for the material/compositions having different oxidation rates and/or etch selectivity. In some embodiments where the sacrificial layers 122 include SiGe and the channel layers 124 include Si, the Si oxidation rate of the channel layers 124 is less than the SiGe oxidation rate of the sacrificial layers 122.

The channel layers 124 or portions thereof may form nanosheet channel(s) of the multi-gate transistor. The term nanosheet is used herein to designate any material portion with nanoscale, or even microscale dimensions, and having an elongate shape, regardless of the cross-sectional shape of this portion. Thus, this term designates both circular and substantially circular cross-section elongate material portions, and beam or bar-shaped material portions including for example a cylindrical in shape or substantially rectangular cross-section. The channel layers 124 may be referred to as semiconductor channels in the context. The use of the channel layers 124 to define a channel or channels of a device is further discussed below.

In the present embodiments, three layers of the sacrificial layers 122 and three layers of the channel layers 124 are alternately arranged as illustrated in FIG. 1. It can be appreciated that any number of epitaxial layers can be formed in the epitaxial stack 120; the number of layers depending on the desired number of channels regions for the transistor. In some embodiments, the number of channel layers 124 is between 2 and 10. The sacrificial layers 122 in channel regions(s) may eventually be removed and serve to define a vertical distance between adjacent channel region(s) for a subsequently-formed multi-gate device. In the present embodiments, the sacrificial layer 122 may have a thickness greater than that of the channel layers 124. In some other embodiments, the sacrificial layer 122 may have a thickness equal to or less than that of the channel layers 124.

By way of example, epitaxial growth of the layers of the stack 120 may be performed by a molecular beam epitaxy (MBE) process, a metalorganic chemical vapor deposition (MOCVD) process, and/or other suitable epitaxial growth processes. In some embodiments, the epitaxially grown layers such as, the channel layers 124 include suitable semiconductor material, such as like Si, Ge, Sn, SiGe, GeSn, III-V semiconductor, the like, or the combination thereof. In some embodiments, the channel layers 124 may include a same semiconductor material as that substrate 110. In some embodiments, the epitaxially grown sacrificial layers 122 include a different material than the substrate 110. For example, the sacrificial layers 122 include suitable semiconductor material, such as Si, Ge, SiGe, GeSn, III-V semiconductor, the like, or the combination thereof. In some other embodiments, at least one of the layers 122 and 124 may include other materials such as a compound semiconductor such as silicon carbide, gallium arsenide, gallium phosphide, indium phosphide, indium arsenide, and/or indium antimonide, an alloy semiconductor such as GaAsP, AlInAs, AlGaAs, InGaAs, GaInP, and/or GaInAsP, or combinations thereof. As discussed, the materials of the layers 122 and 124 may be chosen based on providing differing oxidation and/or etching selectivity properties. In some embodiments, the layers 122 and 124 are substantially dopant-free (i.e., having an extrinsic dopant concentration from about 0 cm⁻³ to about 1×10¹⁸ cm⁻³), where for example, no intentional doping is performed during the epitaxial growth process.

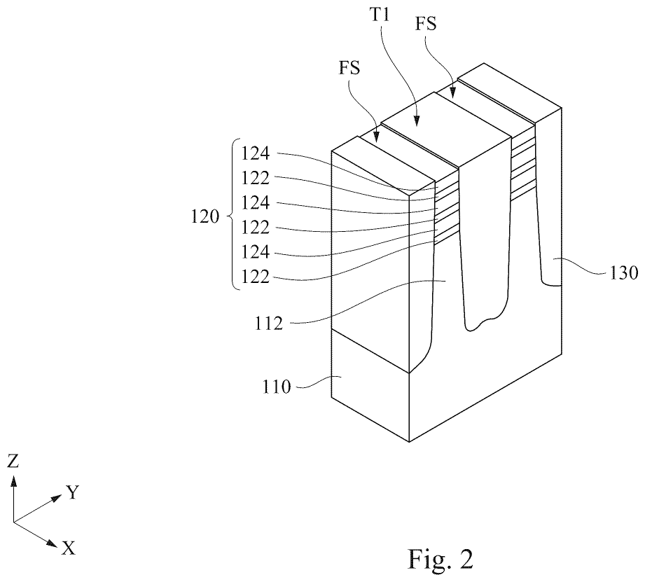

Reference is made to FIG. 2. A plurality of semiconductor fins FS extending from the substrate 110 are formed. The semiconductor fins FS may extend substantially along a same direction X. In various embodiments, each of the fins FS includes a substrate portion 112 formed from the substrate 110 and portions of each of the epitaxial layers of the epitaxial stack 120 including epitaxial layers 122 and 124. The fins FS may be fabricated using suitable processes including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in some embodiments, a sacrificial layer is formed over a substrate and patterned using a photolithography process. Spacers are formed alongside the patterned sacrificial layer using a self-aligned process. The sacrificial layer is then removed, and the remaining spacers, or mandrels, may then be used to pattern the fins FS by etching initial epitaxial stack 120. The etching process can include dry etching, wet etching, reactive ion etching (RIE), and/or other suitable processes.

The fins FS may subsequently be fabricated using suitable processes including photolithography and etch processes. The photolithography process may include forming a hard mask layer over the epitaxial stack 120, forming a photoresist layer (not shown) over the hard mask layer, exposing the photoresist to a pattern, performing post-exposure bake processes, and developing the resist to form a patterned mask including the resist. In some embodiments, patterning the resist to form the patterned mask element may be performed using an electron beam (e-beam) lithography process or an extreme ultraviolet (EUV) lithography process. The patterned mask may then be used to protect regions of the substrate 110, and layers formed thereupon, while an etch process forms trenches Tl in unprotected regions through the hard mask layer, through the epitaxial stack 120, and into the substrate 110, thereby leaving the plurality of extending fins FS. The trenches Tl may be etched using a dry etch (e.g., reactive ion etching), a wet etch, and/or combination thereof. Numerous other embodiments of methods to form the fins on the substrate may also be used including, for example, defining the fin region (e.g., by mask or isolation regions) and epitaxially growing the epitaxial stack 120 in the form of the fins FS. The hard mask layer may be removed from the fins FS by suitable process after the fin patterning process.

Isolation structures 130 are formed in the trench Tl between the fins FS. The isolation structure 130 may be a single-layer or a multi-layer structure. In some embodiments, the isolation structure 130 includes low-k (k<7) dielectric materials, SiN, SiCN, SiOC, SiOCN or the like. Formation of the isolation structure 130 may include depositing a dielectric material over the fins FS, followed by a planarization process (e.g., chemical mechanical planarization (CMP)).

Reference is made to FIG. 3. One or more dummy gate structures 140 are formed on the epitaxial stack 120. The dummy gate structure 140 may include a gate dielectric 142, a gate electrode 144, and a hard mask 146. The gate dielectric 142 may include one or more layers of dielectric material, such as silicon oxide, silicon nitride, a high-k dielectric material, and/or other suitable dielectric material. In some embodiments, the gate electrode 144 includes a material different than that of the gate dielectric 142. In some embodiments, the gate dielectric 142 may be deposited by a CVD process, a sub-atmospheric CVD (SACVD) process, a FCVD process, an ALD process, a PVD process, or other suitable process. The gate electrode 144 may include polycrystalline silicon (polysilicon). The hard mask 146 may include silicon oxide, silicon nitride, the like, or the combination thereof. For example, the hard mask 146 include a silicon nitride layer 146a and a silicon oxide layer 146b (referring to FIG. 4A) over the silicon nitride layer 146a. In some embodiments, the materials of the dummy gate structures 140 are formed by various processes such as layer deposition, for example, CVD, PVD, ALD, thermal oxidation, or other suitable deposition techniques, or combinations thereof.

The dummy gate structures 140 may be formed by first depositing a blanket gate dielectric layer, a gate electrode layer, and a mask layer, followed by pattern and etch processes. For example, the pattern process includes a lithography process (e.g., photolithography or e-beam lithography) which may further include photoresist coating (e.g., spin-on coating), soft baking, mask aligning, exposure, post-exposure baking, photoresist developing, rinsing, drying (e.g., spin-drying and/or hard baking), other suitable lithography techniques, and/or combinations thereof. In some embodiments, the etch process may include dry etch (e.g., RIE), wet etch, other etch methods, and/or combinations thereof. By patterning the dielectric layer, the gate electrode layer, and the mask layer, the fins FS are partially exposed on opposite sides of the dummy gate structure 140.

Gate spacers 150 are formed on opposite sidewalls of the dummy gate structures 140. The gate spacers 150 may be made of a dielectric material such as silicon oxide, silicon nitride, silicon carbide, silicon oxynitride, SiCN, silicon oxycarbide, SiOCN, other low-k dielectric, the like, and/or combinations thereof. The gate spacers 150 may a single layer or multiple layers. For example, the gate spacers 150 include a first gate spacer 152 and a second gate spacer 154 over the first gate spacer 152, in which the composition of the first gate spacer 152 and the second gate spacer 154 may be different from each other. Formation of the gate spacers 150 may include conformally depositing a spacer layer by ALD or CVD processes, followed by an anisotropic etching process.

In some embodiments, after the formation of the gate spacers 150 and the dummy gate structures 140, an etching back process is performed to lower a top surface of the isolation structure 130 (referring to FIG. 2). For example, the top surface of the isolation structure 130 (referring to FIG. 2) is lowered to a position lower than a bottom surface of a bottom most one of the sacrificial layers 122, such that the sacrificial layers 122 and the channel layers 124 are exposed.

Reference is made to FIGS. 4A and 4B. After the formation of the gate spacers 150 and the dummy gate structures 140, exposed portions of the semiconductor fins FS that extend laterally beyond the gate spacers 150 (e.g., in source/drain regions of the fins FS) are etched by using, for example, an anisotropic etching process that uses the dummy gate structures 140 and the gate spacers 150 as an etch mask, resulting in recesses R1 into the semiconductor fins FS and between corresponding dummy gate structures 140. After the anisotropic etching, end surfaces of the sacrificial layers 122 and the channel layers 124 are exposed by the recesses R1 and aligned with respective outermost sidewalls of the gate spacers 150, due to the anisotropic etching. In some embodiments, the anisotropic etching may be performed by a dry chemical etch (e.g., reactive-ion etching) using suitable reaction gas, such as a fluorine-based gas (such as SF₆, CH₂F₂, CH₃F, CHF₃, or the like), chloride-based gas (e.g., Cl₂), hydrogen bromide gas (HBr), oxygen gas (O₂), the like, or combinations thereof.

The sacrificial layers 122 are laterally or horizontally recessed by using suitable selective etching process, resulting in lateral/sidewall recesses R2 vertically between corresponding channel layers 124, and vertically between the channel layer 124 and the substrate portion 112. For example, end surfaces of the sacrificial layers 122 are recessed by the selective etching process. The various compositions in epitaxial layers result in different oxidation rates and/or etch selectivity, thereby facilitating the selective etching process. In some embodiments, a selective dry etching process is performed by using fluoride-based etchant gas, such as NF₃, SF₆, the like, or the combination thereof. The fluoride-based gas may etch SiGe at a faster etch rate than it etches Si. The substrate portion 112 and the channel layers 124 may have a higher etch resistance to the selective etching process than that of the sacrificial layers 124. In some embodiments, the selective etching includes SiGe oxidation followed by a SiGeOₓ removal. For example, the oxidation may be provided by an oxygen-containing cleaning process and then SiGeOₓ removed by the fluoride-based plasma (e.g., NF₃ plasma) that selectively etches SiGeOₓ at a faster etch rate than it etches Si. Moreover, because oxidation rate of Si is much lower (sometimes 30 times lower) than oxidation rate of SiGe (or Ge), the channel layers 124 and the substrate portion 112 may not be not significantly etched by the process of laterally recessing the sacrificial layers 124. As a result, the channel layers 124 and the substrate portion 112 laterally extend past opposite end surfaces of the sacrificial layers 124.

Inner spacers INS are formed in the recesses R2. Stated differently, the inner spacers INS may be formed on opposite end surfaces of the laterally recessed sacrificial layers 124. The inner spacers INS may include a low-k dielectric material, such as SiOₓ, SiON, SiOC, SiN, SiCN, or SiOCN. Formation of the inner spacers INS may include depositing an inner spacer material layer, followed by an anisotropic etching process to trim the deposited inner spacer material layer. Through the anisotropic etching process, only portions of the deposited inner spacer material layer that fill the lateral/sidewall recesses R3 are left. The inner spacers INS may include a single layer or multiple layers. The inner spacers INS may serve to isolate metal gates from source/drain regions formed in subsequent processing.

Epitaxial features 160 may be formed in the respective recesses R1. In some embodiments, an epitaxial growth process is performed to grow an epitaxial material in the recesses R1. The epitaxial material may have a composition similar to the substrate 110. For example, the substrate 110 and the epitaxial features 160 are Si. In some alternative embodiments, the epitaxial features 160 may have a composition different from that of the substrate 110. For example, the substrate 110 includes Si, and the epitaxial features 160 may include SiGe.

In some embodiments, the epitaxial features 160 are not intentionally doped, for example, not having intentionally placed dopants, but rather having a doping resulting from process contaminants. For example, the epitaxial features 160 are not intentional doped (NID) semiconductor layers and thus free from p-type dopants (e.g., boron) and n-type dopants (e.g., phosphorous) in subsequent doped source/drain epitaxial features. Alternatively, the epitaxial features 160 may be doped with p-type dopants (e.g., boron) or n-type dopants (e.g., phosphorous), and with a doping concentration lower than that of the doped source/drain epitaxial features. For example, the epitaxial features 160 have dopant concentration lower than about 10¹³/cm³.

In some embodiments, in order to prevent the epitaxial material of the epitaxial features 160 from being inadvertently formed on end surfaces of the channel layers 124, the epitaxial features 160 can be grown in a bottom-up manner, in accordance with some embodiments of the present disclosure. By way of example and not limitation, the epitaxial features 160 can be grown by an epitaxial deposition/partial etch process, which repeats the epitaxial deposition/partial etch process at least once. Such repeated deposition/partial etch process is also called a cyclic deposition-etch (CDE) process. In some embodiments, these epitaxial features 160 are grown by selective epitaxial growth (SEG), where an etching gas is added to promote the selective growth of the epitaxial material from the bottom surface of the recesses R1 that has a first crystal plane, but not from the vertical end surfaces of the channel layers 124 that have a second crystal plane different from the first crystal plane.

Source/drain epitaxial structures 180 are on opposite sides of the channel layers 124 and over the epitaxial features 160. The formation of the source/drain epitaxial structure 180 may be formed by performing an epitaxial growth process that provides an epitaxial material on the sides of the channel layers 124. Suitable epitaxial processes include CVD deposition techniques (e.g., vapor-phase epitaxy (VPE) and/or ultra-high vacuum CVD (UHV-CVD)), molecular beam epitaxy, and/or other suitable processes. The epitaxial growth process may use gaseous and/or liquid precursors, which interact with the composition of semiconductor materials of the channel layers 124.

In some embodiments, the source/drain epitaxial structure 180 may include Ge, Si, GaAs, AlGaAs, SiGe, GaAsP, SiP, or other suitable material. The source/drain epitaxial structure 180 may be in-situ doped during the epitaxial process by introducing first-type doping species. In some embodiments, where a p-type device is to be formed the source/drain epitaxial structure 180 (e.g., the source/drain epitaxial structure 180A) is doped by p-type dopants, such as boron or BF₂. In some embodiments where an n-type device is to be formed, the source/drain epitaxial structure 180 (e.g., the source/drain epitaxial structure 180B) is doped with n-type dopants, such as phosphorus or arsenic. If the source/drain epitaxial structure 180 are not in-situ doped, an implantation process (i.e., a junction implant process) is performed to dope the source/drain epitaxial structure 180. The source/drain epitaxial structures 180 may have dopant concentration greater than about 10¹⁸/cm³. In some embodiments, the source/drain epitaxial structure 180 has plural epitaxial layers 182, 184, and 186, and the epitaxial layers 182, 184, 186 may include different dopant concentrations from each other and/or different semiconductor compositions from each other for facilitating the epitaxial growth process.

In some embodiments, prior to the formation of the source/drain epitaxial structures 180, a bottom isolation layer 170 is optionally conformally deposited into the recess R1 and over the epitaxial features 160. The bottom isolation layer 170 may be deposited by a deposition/partial etch process, and thus the bottom isolation layer 170 may be located at the bottom of the recess R1, leaving the channel layers 124 exposed. The configuration of the bottom isolation layer 170 can reduce the capacitances between gate and source/drain regions, leakage from source/drain regions to the well region (both source cutoff current (Is_{off}), and junction capacitance between the source/drain regions and the well region. The dielectric material may include silicon oxide, silicon nitride, silicon oxynitride, the like, or the combination thereof. The bottom isolation layer 170 can be a single dielectric layer, or multiple dielectric layers. In some embodiments, for allowing growth of the source/drain epitaxial structures 180 from the bottommost channel layer 124, a top surface of the bottom isolation layer 170 is higher than a top surface of the semiconductor substrate 110 and lower than a bottom surface of the bottommost channel layer 124. The source/drain epitaxial structures 180 grown from the channel layers 124 may have a bottom surface in contact with the bottom isolation layer 170 in the present embodiments. In some other embodiments, the bottom surface of the source/drain epitaxial structures 180 may be spaced apart from with the bottom isolation layer 170 by air gaps.

Reference is made to FIG. 5. After the epitaxial growth of the source/drain epitaxial structures 180, a dielectric material 190 is formed over the substrate 110 and filling the space between the dummy gate structures 140. In some embodiments, the dielectric material 190 includes a contact etch stop layer (CESL) 192 and an interlayer dielectric (ILD) layer 194 formed in sequence. In some examples, the CESL 192 includes a silicon nitride layer, silicon oxide layer, a silicon oxynitride layer, and/or other suitable materials having a different etch selectivity than the ILD layer. The CESL 192 may be formed by plasma-enhanced chemical vapor deposition (PECVD) process and/or other suitable deposition or oxidation processes. The ILD layer 194 is then deposited over the CESL 192. In some embodiments, the ILD layer 194 includes materials such as tetraethylorthosilicate (TEOS) oxide, un-doped silicate glass, or doped silicon oxide such as borophosphosilicate glass (BPSG), fused silica glass (FSG), phosphosilicate glass (PSG), boron doped silicon glass (BSG), and/or other suitable dielectric materials having a different etch selectivity than the CESL 192. The ILD layer 194 may be deposited by a PECVD process or other suitable deposition technique. After depositing the dielectric material 190, a planarization process (e.g., CMP) may be performed to remove excessive materials of the dielectric material 190.

The dummy gate structures 140 (referring to FIGS. 4A and 4B) are replaced with high-k/metal gate structures 200. The high-k/metal gate replacement process may include removing the dummy gate structures 140 (referring to FIGS. 4A and 4B), and removing the sacrificial layers 122 (referring to FIGS. 4A and 4B) therebelow. The removals form gate trenches GT between the gate spacers 150, openings/spaces GO between the bottommost channel layer 124 and the substrate 110 and between neighboring channel layers 124. Replacement gate structures 200 are respectively formed in the gate trenches GT and openings/spaces GO to surround each of the channel layers 124 suspended in the gate trenches GT.

In the illustrated embodiments, the dummy gate structures 140 (referring to FIGS. 4A are 4B) are removed by using a selective etching process (e.g., selective dry etching, selective wet etching, or a combination thereof) that etches the materials in dummy gate structures 140 (referring to FIGS. 4A are 4B) at a faster etch rate than it etches other materials (e.g., gate spacers 150 and the dielectric material 190), thus resulting in gate trenches GT between corresponding gate spacers 150, with the top surface and sidewalls of the fins FS exposed in the gate trenches GT. Subsequently, the sacrificial layers 122 (referring to FIGS. 4A are 4B) in the gate trenches GT are etched by using another selective etching process that etches the sacrificial layers 122 at a faster etch rate than it etches the channel layers 124, thus forming openings/spaces GO between the bottommost channel layer 124 and the substrate 110 and between neighboring channel layers 124. In this way, the channel layers 124 become nanosheets suspended over the substrate 110 and between the source/drain epitaxial structures 180. This step is also called a channel release process. In some embodiments, the nanosheets 124 can be interchangeably referred to as nanostructures, nanowires, nanoslabs and nanorings, depending on their geometry. For example, in some other embodiments the channel layers 124 may be trimmed to have a substantial rounded shape (i.e., cylindrical) due to the selective etching process for completely removing the sacrificial layers 122 (referring to FIGS. 4A are 4B). In that case, the resultant channel layers 124 can be called nanowires.

The gate structures 200 may be final gates of GAA FETs. The final gate structure may be a high-k/metal gate stack, however other compositions are possible. In some embodiments, each of the gate structures 200 forms the gate associated with the multi-channels provided by the plurality of nanosheets 124. For example, high-k/metal gate structures 200 are formed within the openings GO provided by the release of nanosheets 124. In various embodiments, the high-k/metal gate structure 200 includes a gate dielectric layer 202 around the nanosheets 124, a work function metal stack layer 204 formed around the gate dielectric layer 212, and a gate metal layer 206 filling a remainder of gate trenches GT. Formation of the high-k/metal gate structures 200 may include one or more deposition processes to form various gate materials, followed by a CMP processes to remove excessive gate materials.

In some embodiments, the gate dielectric layer 202 includes an interfacial layer 202a formed around the nanosheets 124 and a high-k gate dielectric layer 202b formed around the interfacial layer 202a. The interfacial layer 202a may be silicon oxide formed on exposed surfaces of semiconductor materials in the gate trenches GT by using, for example, thermal oxidation, chemical oxidation, wet oxidation or the like. As a result, surface portions of the nanosheets 124 and the substrate 110 exposed in the gate trenches GT are oxidized into silicon oxide to form interfacial layer 202a. The interfacial layer 202a may be doped with nitrogen. The k value of the high-k gate dielectric layer 202b may be greater than about 9, or even greater than about 13. In some embodiments, the high-k gate dielectric layer 202b includes dielectric materials such as hafnium oxide (HfO₂), hafnium silicon oxide (HfSiO), hafnium silicon oxynitride (HfSiON), hafnium tantalum oxide (HfTaO), hafnium titanium oxide (HfTiO), hafnium zirconium oxide (HfZrO), lanthanum oxide (LaO), zirconium oxide (ZrO), titanium oxide (TiO), tantalum oxide (Ta₂O₅), yttrium oxide (Y₂O₃), strontium titanium oxide (SrTiO₃, STO), barium titanium oxide (BaTiO₃, BTO), barium zirconium oxide (BaZrO), hafnium lanthanum oxide (HfLaO), lanthanum silicon oxide (LaSiO), aluminum silicon oxide (AlSiO), aluminum oxide (Al₂O₃), other metal-containing dielectrics, the like, or combinations thereof.

In some embodiments, the work function metal stack layer 204 may include one or more work function metal layers stacked one over another. The work function metal stack layer 204 provide a suitable work function for the high-k/metal gate structures 210. The work function metal layers may include TIN, TaN, TiAl, TiAIN, TaAl, TaAIN, TaAIC, TaCN, WNC, Co, Ni, Pt, W, or combination thereof. NMOSFET and PMOSFET may include the same work function material, or different work function materials. For example, n-type work function metals for NMOSFET may exemplarily include, but are not limited to, titanium aluminide (TiAl), titanium aluminium nitride (TiAIN), carbo-nitride tantalum (TaCN), hafnium (Hf), zirconium (Zr), titanium (Ti), tantalum (Ta), aluminum (Al), metal carbides (e.g., hafnium carbide (HfC), zirconium carbide (ZrC), titanium carbide (TIC), aluminum carbide (AIC)), aluminides, and/or other suitable materials. P-type work function metal for PMOSFET may exemplarily include, but are not limited to, titanium nitride (TiN), tungsten nitride (WN), tungsten (W), ruthenium (Ru), palladium (Pd), platinum (Pt), cobalt (Co), nickel (Ni), conductive metal oxides, and/or other suitable materials. One for more lithography and patterning processes may be performed for forming the work-function metals for NMOSFET and forming the work-function metals for PMOSFET. In some embodiments, the gate metal layer 206 may exemplarily include, but are not limited to, tungsten, aluminum, copper, nickel, cobalt, titanium, tantalum, titanium nitride, tantalum nitride, nickel silicide, cobalt silicide, TaC, TaSiN, TaCN, TiAl, TiAIN, or other suitable materials.

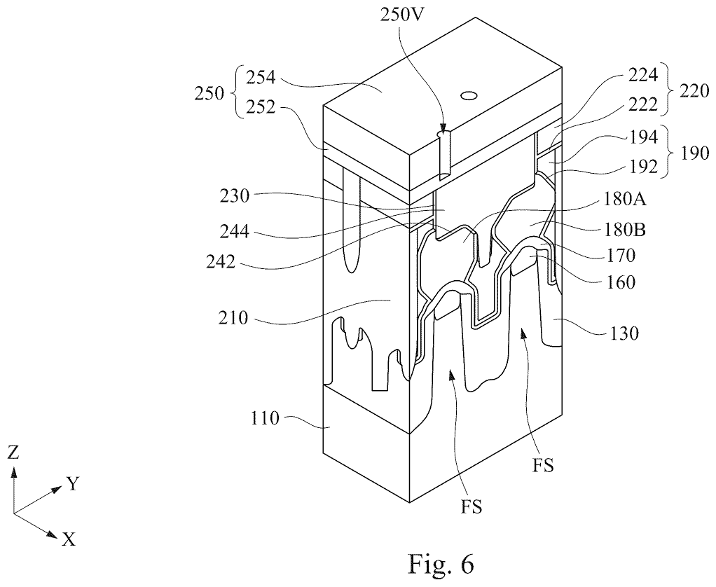

Reference is made to FIG. 6. Source/drain contacts 244 are formed over the source/drain epitaxial structures 180. In some embodiments, a dielectric material 220 is formed over the structure of FIG. 5, in which the dielectric material 220 includes an etch stop layer 222 and an ILD layer 224 formed in sequence. The formation of the source/drain contacts 244 includes etching source/drain contact openings through the dielectric materials 190 and 220 to expose top surfaces of the source/drain epitaxial structures 180. Subsequently, dielectric liners 230 may be formed on sidewalls of the source/drain contact openings through the dielectric materials 190 and 220. Formation of the dielectric liners may include conformally depositing a dielectric liner layer over the dielectric material 220 and into the source/drain contact openings, and removing a bottom portion of the dielectric liner layer to expose the source/drain epitaxial structures 180. The removal of the bottom portion of the dielectric liner layer may include a clean or etch process. Then, one or more metal materials are deposited into the source/drain contact openings. The metal materials may include W, Ru, Co, Cu, Ti, TiN, Ta, TaN, Mo, Ni, Pt, Ir, Rh, the like or combinations thereof. The metal materials are deposited to fill the source/drain contact openings by using suitable deposition techniques (e.g., CVD, PVD, ALD, the like or combinations thereof). Subsequently, a CMP process can be performed to remove excess metal materials outside the source/drain contact openings, while leaving metal materials in the source/drain contact openings to serve as the source/drain contacts 244. The source/drain contacts 244 may include a single metal material or multiple metal material layers.

In some embodiments, prior to depositing the metal materials of the source/drain contacts 244, metal silicide regions 242 may be formed on exposed top surfaces of the source/drain epitaxial structures 180 by using a silicidation process. Silicidation may be formed by blanket depositing a metal layer over the exposed source/drain epitaxial structures 180, annealing the metal layer such that the metal layer reacts with silicon (and germanium if present) in the source/drain epitaxial structures 180 to form the metal silicide regions 242, and thereafter removing the non-reacted metal layer. In some embodiments, the metal layer used in the silicidation process includes nickel, cobalt, titanium, tantalum, platinum, tungsten, other noble metals, other refractory metals, rare earth metals or their alloys. Thus, metal silicide regions 242 may be between the source/drain contacts 244 and the source/drain epitaxial structures 180.

In some embodiments, prior to the formation of the dielectric material 220 and the source/drain contacts 244, gate end dielectrics CF may either be disposed between gate structures 200 or at an end of a gate structure 200 after a gate cut process. In some embodiments, the gate end dielectric CF may be referred to as dielectric plugs. The gate end dielectric CF may include suitable dielectric materials, such as oxide, Si₃N₄, other nitride-based dielectric, carbon-based dielectric, high k material (e.g., having a k value equal to or greater than 9), or other suitable dielectric material. Formation of the gate end dielectric CF may include etching away portions of the metal gate structures 210 and the hard masks 220 to expose underlying dielectric materials (e.g., the isolation structures 130), and depositing the suitable gate end dielectric materials over the underlying dielectric materials (e.g., the isolation structures 130). A CMP process may be performed to remove excess portions of the gate end dielectric materials, leaving the remaining portions forming the gate end dielectric CF.

In some embodiments, a dielectric material 250 is formed over the source/drain contacts 244, in which the dielectric material 250 includes an etch stop layer 252 and an ILD layer 254 formed in sequence. Details of the etch stop layers 222 and 252 and the ILD layers 224 and 254 are similar to those mentioned with respect to the CESL 192 and the ILD layer 194, and thereto not repeated herein. The dielectric material 250 may be etched with via openings 250V corresponding to the underlying source/drain contacts 244.

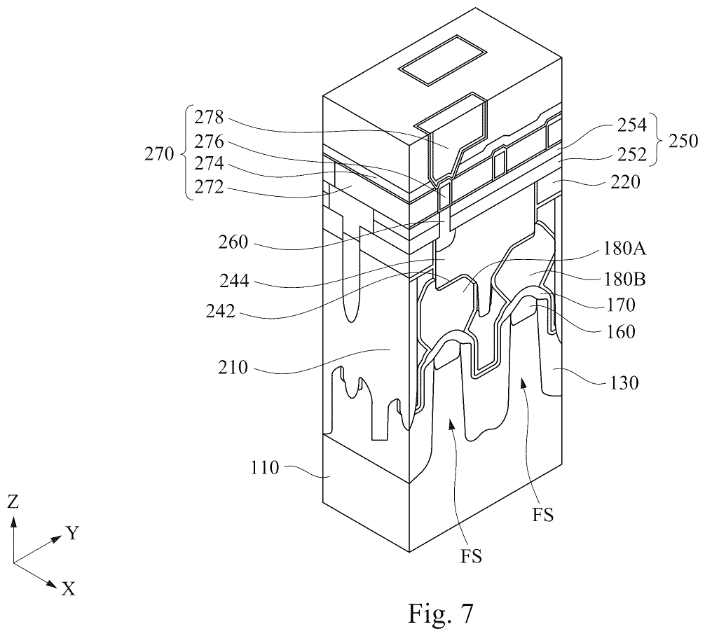

Reference is made to FIG. 7. Metal vias 260 and a front-side multilayer interconnection (MLI) structure 270 are over the substrate 110. Formation of the metal vias 260 may include further etching the via openings 250V (referring to FIG. 6) in the dielectric material 250 to expose the underlying source/drain contacts 244, and filling the via openings 250V (referring to FIG. 6) with one or more suitable conductive materials. The conductive materials may comprise metal materials such as W, Ru, Co, Cu, Ti, TiN, Ta, TaN, Mo, Ni, combinations thereof, or the like. A planarization process (e.g., CMP) may be performed to remove excessive materials of the conductive materials. Remaining portions of the conductive materials in the via openings 250V (referring to FIG. 6) may form the metal vias 260, respectively. The metal via 260 may be in contact with the source/drain contact 244.

The front-side MLI structure 270 is formed over the metal vias 260. The front-side MLI structure 270 may include at least one metallization layers. The number of metallization layers may vary according to design specifications of the integrated circuit structure. The metallization layers each comprise one or more inter-metal dielectric (IMD) layers, one or more horizontal interconnects respectively extending horizontally in the IMD layers. For example, the metallization layer comprises IMD layers 272 and horizontal interconnects (e.g., metal lines 278) extending horizontally in the IMD layers 272 and/or one or more vertical interconnects (e.g., metal via 276) respectively extending vertically in the IMD layers 272. The front-side MLI structure 270 may have etch stop layers 274 between two adjacent IMD layers 272.

The metallization layer can be formed using, for example, a single damascene process, a dual damascene process, the like, or combinations thereof. In some embodiments, the IMD layers 272 may include low-k dielectric materials having k values, for example, lower than about 4.0 or even 2.0 disposed between such conductive features. In some embodiments, the IMD layers 272 may be made of, for example, PSG, BPSG, FSG, SiOₓC_{y}, Spin-On-Glass, Spin-On-Polymers, silicon oxide, silicon oxynitride, combinations thereof, or the like, formed by any suitable method, such as spin-on coating, CVD, PECVD, or the like. The metal lines 278 may comprise metal materials such as W, Ru, Co, Cu, Ti, TiN, Ta, TaN, Mo, Ni, combinations thereof, or the like. In some embodiments, the metal lines 276 may further comprise one or more barrier/adhesion layers (not shown) to protect the respective IMD layers 272 from metal diffusion (e.g., copper diffusion) and metallic poisoning. The one or more barrier/adhesion layers may comprise titanium, titanium nitride, tantalum, tantalum nitride, or the like, and may be formed using PVD, CVD, ALD, or the like.

Reference is made to FIG. 8. The structure of FIG. 7 is bonded with a carrier substrate, and flipped upside down after bonding. A thinning process may be performed on a backside of the substrate 110, thereby reducing a thickness of the substrate 110. Subsequently, a bilayer hard mask layer including a hard mask layer 270 and a hard mask layer 280 is formed on the backside of the substrate 110. The hard mask layer 270 and the hard mask layer 280 may include different materials. The hard mask layer 270 may include suitable dielectric materials, such as Si₃N₄, other nitride-based dielectric, carbon-based dielectric, high k material (e.g., having a k value equal to or greater than 9), or other suitable dielectric material. The hard mask layer 270 may include suitable dielectric materials, such as Si₃N₄, other nitride-based dielectric, carbon-based dielectric, high k material (e.g., having a k value equal to or greater than 9), or other suitable dielectric material. The hard mask layer 280 may include suitable dielectric materials, such as silicon oxide, other oxide-based dielectric, or other suitable dielectric material. The hard mask layers 270 and 280 may be deposited by suitable CVD process. In the context, for clear illustration, the substrate 110 has a region BIR where backside dielectric plugs are to be formed and a region BCR where backside contact via are to be formed.

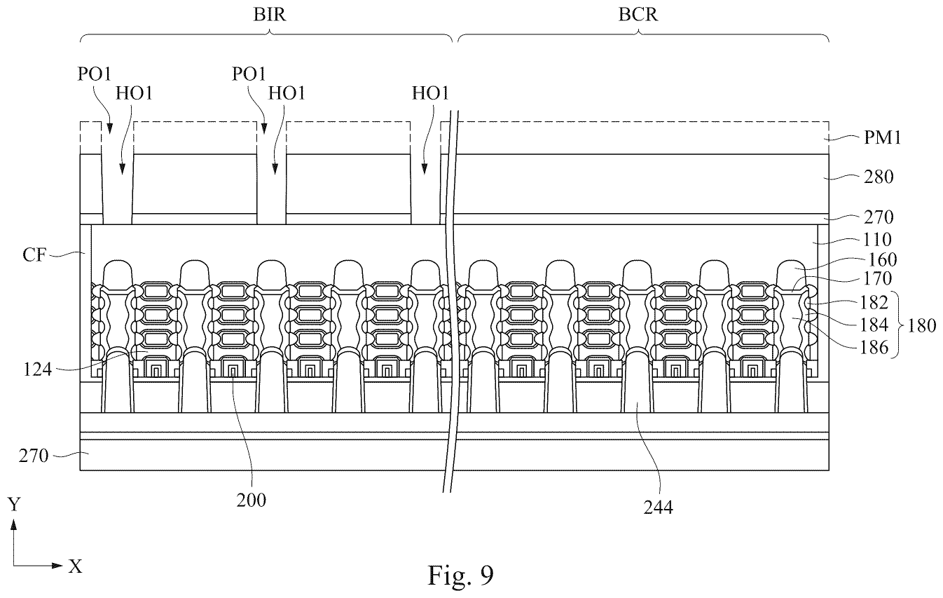

Reference is made to FIG. 9. A high-resolution photoresist mask PM1 may be formed over the hard mask layer 280. The high-resolution photoresist mask PM1 may cover the region BCR and have openings PO1 vertically aligned with the source/drain epitaxial structures 180 in the region BIR. In some embodiments, the high-resolution photoresist mask PM1 may include a photoresist formed by a high-resolution photolithography process, such as extreme ultraviolet (EUV) photolithography process. An exemplary high-resolution photolithography process may include processing steps of photoresist coating, soft baking, mask aligning, exposing, post-exposure baking, developing photoresist and hard baking.

Using the high-resolution photoresist mask PM1 as an etch mask, an etching process is performed to etch openings HO1 in the hard mask layers 280 and 270, thereby exposing the backside of the substrate 110. After the etching process, the photoresist mask PM1 may be removed by suitable stripping or ashing process.

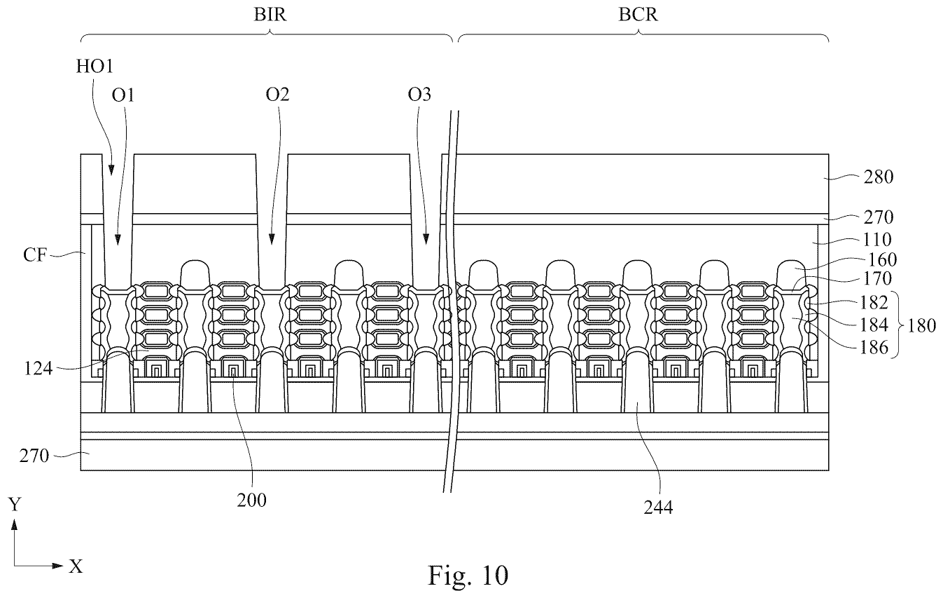

Reference is made to FIG. 10. Using the hard mask layer 280 as an etch mask, a first etching process is performed to etch openings O1-O3 in the region BIR of the substrate 110. The first etching process may remove the epitaxial features 160 and expose the bottom isolation layer 170. For example, the first etching process etches the epitaxial features 160 and the substrate 110 at a fast etch rate than it etches the bottom isolation layer 170, such that the bottom isolation layer 170 may serve as a etch stop layer and protect the underlying source/drain epitaxial structure 180 during the etching process.

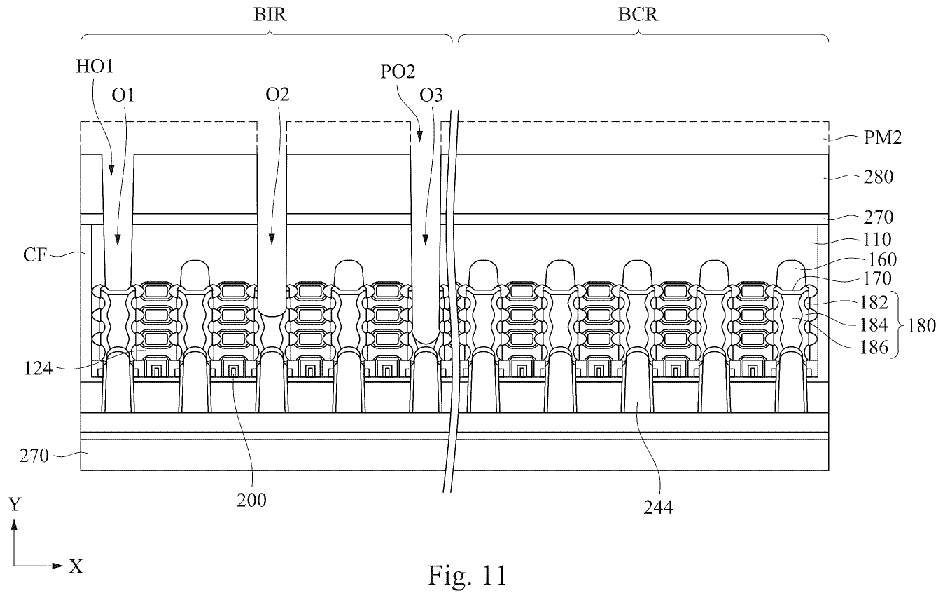

Reference is made to FIG. 11. A photoresist mask PM2 having openings PO2 may be formed over the hard mask layer 280. The photoresist mask PM2 may cover the region BCR and the opening O1 in the region BIR and exposing the openings O2-O3 in the region BIR by the openings PO2. In some embodiments, the photoresist mask PM2 may include a photoresist formed by a photolithography process, in which a wavelength of the exposure light thereof is longer than a wavelength of the EUV light used for the high-resolution photoresist mask PM1 (referring to FIG. 9). An exemplary photolithography process may include processing steps of photoresist coating, soft baking, mask aligning, exposing, post-exposure baking, developing photoresist and hard baking.

Using the photoresist mask PM2 as an etch mask, a second etching process is performed to deepen the openings O2-O3. For example, after the second etching process, the openings O2-O3 is laterally located between the bottommost ones of the nanosheets 124. After the second etching process, the photoresist mask PM2 may be removed by suitable stripping or ashing process.

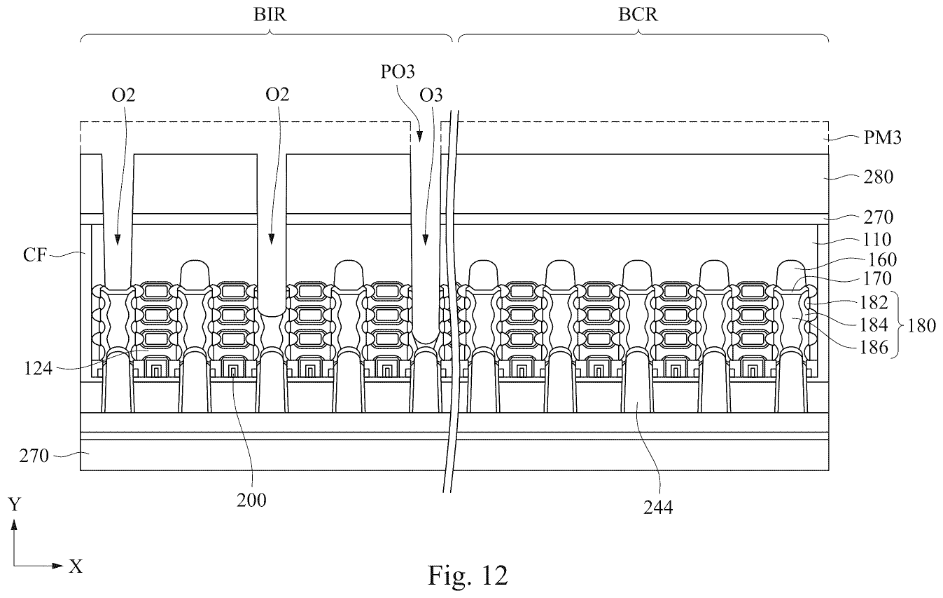

Reference is made to FIG. 12. A photoresist mask PM3 having openings PO3 may be formed over the hard mask layer 280. The photoresist mask PM3 may cover the region BCR and the openings O1 and O2 in the region BIR and exposing the opening O3 in the region BIR by the openings PO3. In some embodiments, the photoresist mask PM3 may include a photoresist formed by a photolithography process, in which a wavelength of the exposure light thereof is longer than a wavelength of the EUV light used for the high-resolution photoresist mask PM1 (referring to FIG. 9). An exemplary photolithography process may include processing steps of photoresist coating, soft baking, mask aligning, exposing, post-exposure baking, developing photoresist and hard baking.

Using the photoresist mask PM3 as an etch mask, a third etching process is performed to deepen the opening O3. For example, after the third etching process, the opening O3 is laterally located between the second bottommost ones of the nanosheets 124. After the third etching process, the photoresist mask PM3 may be removed by suitable stripping or ashing process.

The first to third etching processes in FIGS. 10-12 may use different etch recipes. For example, the first etching process in FIG. 10 uses a first gas etchant for removing the semiconductor materials in the substrate 110 and not substantially remove the bottom isolation layer 170. For example, the second etching process in FIG. 11 uses a second gas etchant for removing the bottom isolation layer 170 and a small amount of the semiconductor materials in the source/drain epitaxial structures 180. The third etching process in FIG. 12 uses a third gas etchant for removing the semiconductor materials in the source/drain epitaxial structures 180. The first to third gas etchant may be different from each other. In some other embodiments, one or more of the first to third etching processes may use two or more gas etchants, and the first to third etching processes may share some of the gas etchants at some stages. In some embodiments of the present disclosure, by applying the multiple masks (e.g., masks PM1-PM3), a depth control backside process is performed to form different etch depths on a same wafer. In some embodiments, one depth corresponds to one low end mask/one etch recipe. For example, a bottom of the opening O3 is lower than a bottom of the opening O2, and the bottom of the opening O2 is lower than a bottom of the opening O1.

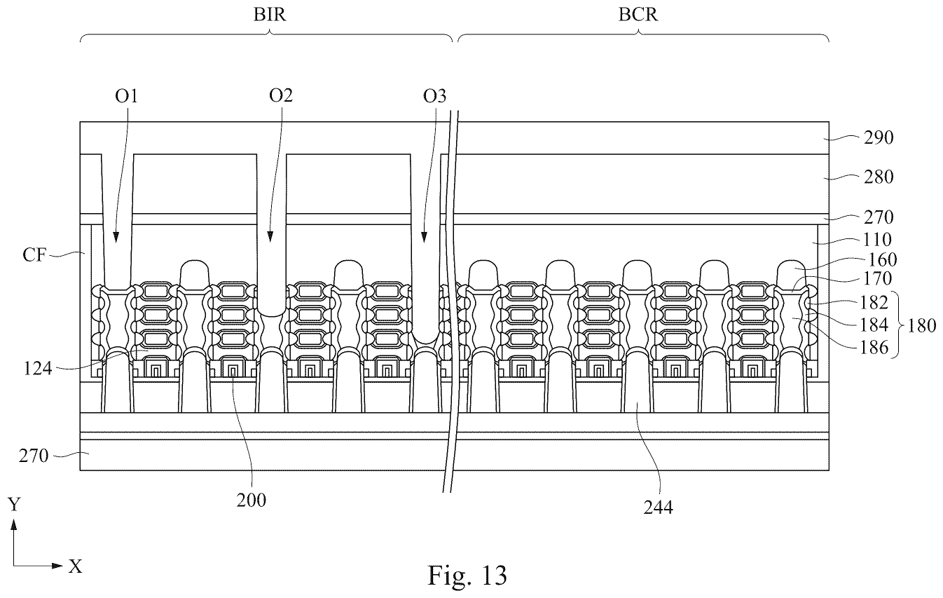

Reference is made to FIG. 13. A dielectric fill material 290 is deposited over the hard mask layer 280 and into the openings O1-O3. The dielectric fill material 290 may be made of SiO₂, Si₃N₄, SiN, polyimide (PI), any other low-k dielectrics, the like, or the combination thereof. For example, the dielectric fill material 290 may include low-k dielectric materials having k values, for example, lower than about 4.0 or even 2.0.

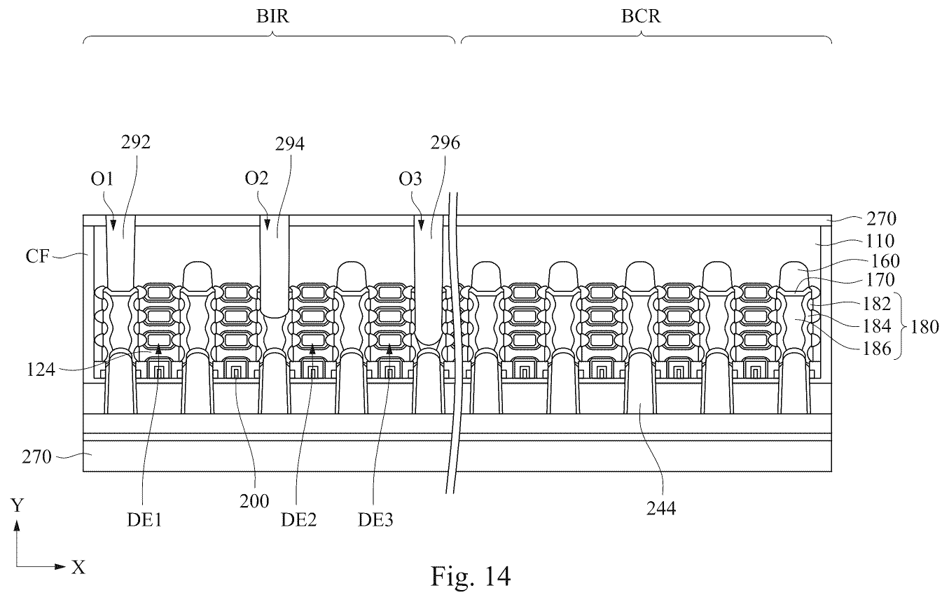

After the deposition of the dielectric fill material 290, a planarization process may be performed to remove excessive materials of the dielectric fill material 290. For example, a planarization process includes a chemical mechanical planarization (CMP) process which removes top portions of the dielectric fill material 290 overlying the hard mask layer 280 and planarizes a top surface of the semiconductor device. In the present embodiments, the CMP process also removes the hard mask layer 280. The resulted structure is shown in FIG. 14. As shown in FIG. 14, after the planarization process, remaining portions of the dielectric fill material 290 (referring to FIG. 13) forms dielectric plugs 292, 294, and 296 in the openings O1-O3, respectively.

The dielectric plug 292 is in contact with the bottom isolation layer 170 and spaced apart from the source/drain epitaxial structures 180 by the bottom isolation layer 170. The dielectric plug 294 is in contact with the source/drain epitaxial structures 180 and between the bottommost ones of the nanosheets 124. The dielectric plug 294 is in contact with the source/drain epitaxial structures 180 and between the second bottommost ones of the nanosheets 124. The depth control backside process can achieve flexible number of nanosheets in multi-gate devices. The dielectric plugs 294 and 296 may be referred to as isolation plugs that can cut/block the sheets/channels from backside of the substrate. With the presence of the dielectric plug 292, the GAA device DE1 includes three active channel layers 124. With the presence of the dielectric plug 294, the GAA device DE2 includes two active channel layers 124 and one dummy channel layer 124. With the presence of the dielectric plug 296, the GAA devices DE3 include one channel layers 124 and two dummy channel layer 124.

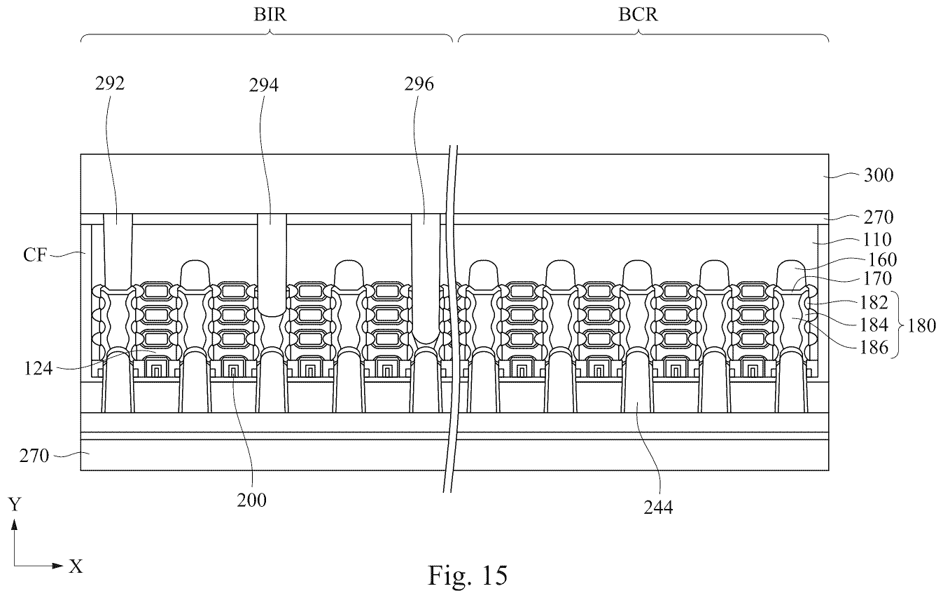

Reference is made to FIG. 15. A hard mask layer 300 is formed on the hard mask layer 270. The hard mask layer 300 may include a different material from the hard mask layer 270. For example, the hard mask layer 300 may include suitable dielectric materials, such as silicon oxide, other oxide-based dielectric, or other suitable dielectric material. The hard mask layer 300 may be deposited by suitable CVD process. Stated differently, an oxide hard mask is redeposited on the hard mask layer 270 for the subsequent backside contact via process.

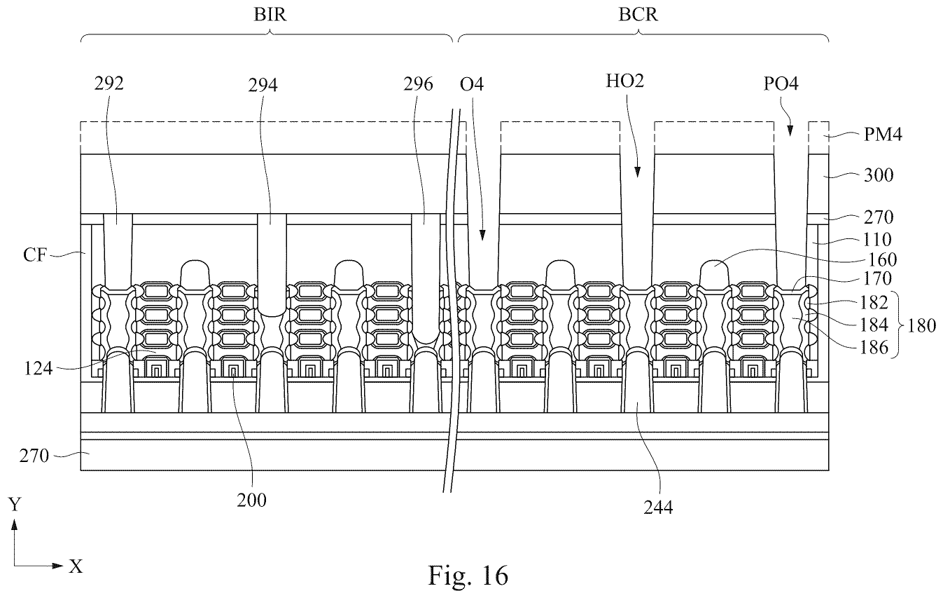

Reference is made to FIG. 16. A high-resolution photoresist mask PM4 may be formed over the hard mask layer 300. The high-resolution photoresist mask PM4 may cover the region BIR and have openings PO4 vertically aligned with the source/drain epitaxial structures 180 in the region BCR. In some embodiments, the high-resolution photoresist mask PM4 may include a photoresist formed by a high-resolution photolithography process, such as extreme ultraviolet (EUV) photolithography process. An exemplary high-resolution photolithography process may include processing steps of photoresist coating, soft baking, mask aligning, exposing, post-exposure baking, developing photoresist and hard baking.

Using the high-resolution photoresist mask PM4 as an etch mask, an etching process is performed to etch openings HO2 in the hard mask layers 300 and 270, thereby exposing the backside of the substrate 110. After the etching process, the photoresist mask PM4 may be removed by suitable stripping or ashing process.

Using the hard mask layer 300 as an etch mask, an etching process is performed to etch openings O4 in the region BCR of the substrate 110. The etching process may remove the epitaxial features 160 and expose the bottom isolation layer 170. The etching process etches the epitaxial features 160 and the substrate 110 at a fast etch rate than it etches the bottom isolation layer 170, such that the bottom isolation layer 170 may serve as a etch stop layer and protect the underlying source/drain epitaxial structure 180 during the etching process.

Reference is made to FIG. 17. Dielectric liners 312 may be formed on sidewalls of the openings O4 in the substrate 110. Material of the dielectric liners 312 may include silicon nitride, silicon oxynitride, silicon carbide, the like, or the combination thereof. Formation of the dielectric liners 312 may include conformally depositing a dielectric liner layer over the hard mask layer 280 and into the openings O4, and removing bottom portions of the dielectric liner layer to expose backsides of the source/drain epitaxial structures 180. The removal of the bottom portion of the dielectric liner layer may include a clean or etch process.

Backside source/drain contacts 322 are formed in the openings O4 over the backsides of the source/drain epitaxial structures 180. The formation of the backside source/drain contacts 322 includes depositing one or more metal materials into the openings O4. The metal materials may include W, Ru, Co, Cu, Ti, TiN, Ta, TaN, Mo, Ni, Pt, Ir, Rh, the like or combinations thereof. The metal materials are deposited to fill the source/drain contact openings by using suitable deposition techniques (e.g., CVD, PVD, ALD, the like or combinations thereof). Subsequently, a CMP process can be performed to remove excess metal materials outside the openings O4, while leaving metal materials in the openings O4 to serve as the backside source/drain contacts 322. The CMP process may also remove the hard mask layer 280 from the hard mask layer 270. The backside source/drain contacts 322 may include a single metal material or multiple metal material layers.

In some embodiments, prior to depositing the metal materials of the backside source/drain contacts 322, metal silicide regions MS may be formed on exposed top surfaces of the source/drain epitaxial structures 180 by using a silicidation process. Silicidation may be formed by blanket depositing a metal layer over the exposed source/drain epitaxial structures 180, annealing the metal layer such that the metal layer reacts with silicon (and germanium if present) in the source/drain epitaxial structures 180 to form the metal silicide regions MS, and thereafter removing the non-reacted metal layer. In some embodiments, the metal layer used in the silicidation process includes nickel, cobalt, titanium, tantalum, platinum, tungsten, other noble metals, other refractory metals, rare earth metals or their alloys. Thus, metal silicide regions MS may be between the backside source/drain contacts 322 and the source/drain epitaxial structures 180.

After the formation of the backside source/drain contacts 322, a backside MLI structure 330 is formed over the backside source/drain contacts 322. The backside MLI structure 330 may include at least one metallization layers. The number of metallization layers may vary according to design specifications of the integrated circuit structure. The metallization layers each comprise one or more inter-metal dielectric (IMD) layers, one or more horizontal interconnects respectively extending horizontally in the IMD layers. For example, the metallization layer comprises IMD layers and horizontal interconnects (e.g., metal lines) extending horizontally in the IMD layers and/or one or more vertical interconnects (e.g., metal via) respectively extending vertically in the IMD layers.

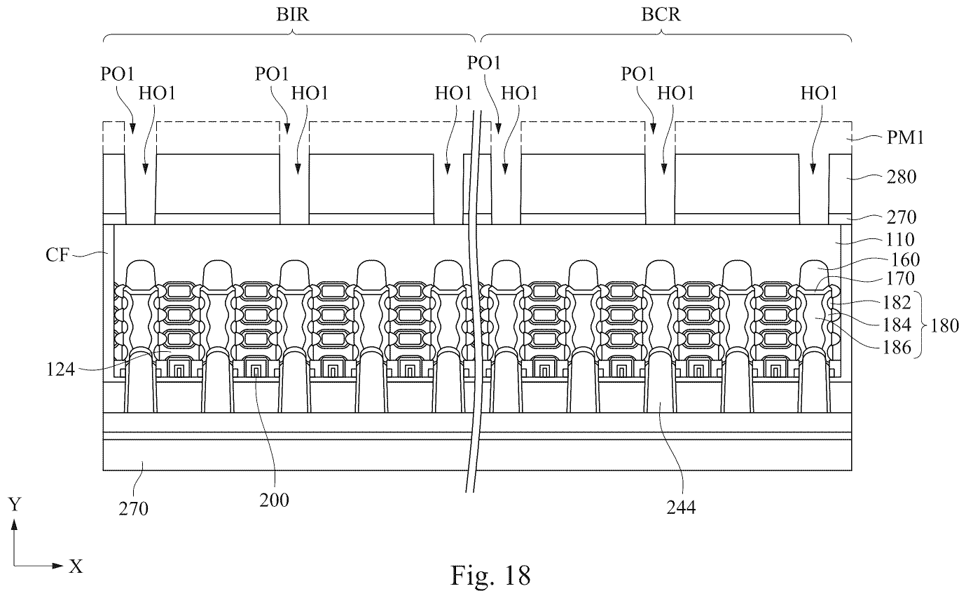

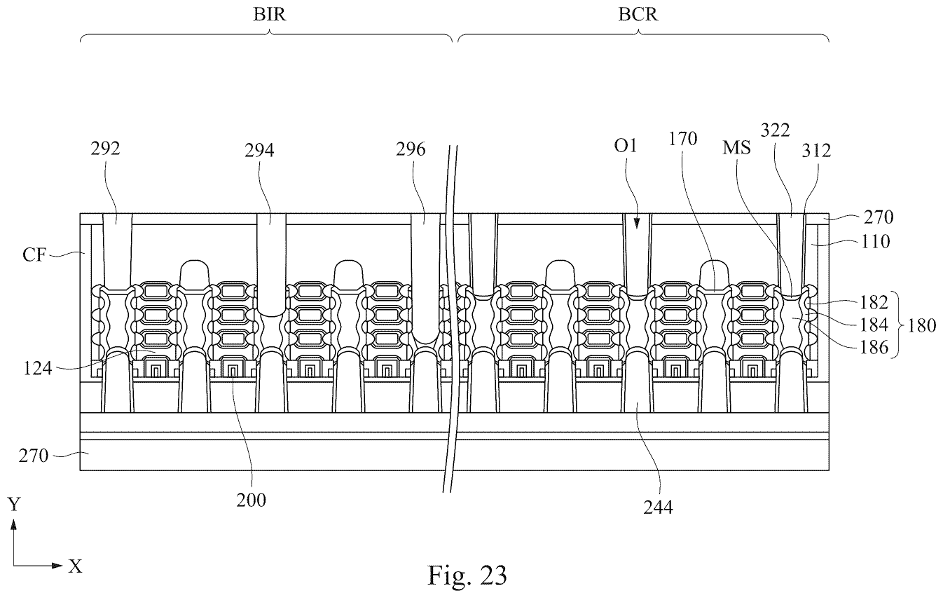

FIGS. 18-23 illustrate cross-sectional views of intermediate stages in the manufacture of a semiconductor device in accordance with some embodiments of the present disclosure. FIGS. 18-23 illustrates cross-sectional views of various regions of the semiconductor device taken along a same direction as the line B-B in FIG. 4A. The illustrated process in FIGS. 18-23 may be performed after the process in FIGS. 1-8, and applicable to manufacture the semiconductor device in FIG. 23. It is understood that additional steps may be provided before, during, and after the steps shown in FIGS. 18-23, and some of the steps described below can be replaced or eliminated for additional embodiments of the method. The order of the operations/processes may be interchangeable.

Reference is made to FIG. 18. A high-resolution photoresist mask PM1 having openings PO1 may be formed over the hard mask layer 280. The high-resolution photoresist mask PM1 may have openings PO1 vertically aligned with the source/drain epitaxial structures 180 in the regions BIR and BCR. In some embodiments, the high-resolution photoresist mask PM1 may include a photoresist formed by a high-resolution photolithography process, such as extreme ultraviolet (EUV) photolithography process. An exemplary high-resolution photolithography process may include processing steps of photoresist coating, soft baking, mask aligning, exposing, post-exposure baking, developing photoresist and hard baking.

Using the high-resolution photoresist mask PM1 as an etch mask, an etching process is performed to etch openings HO1 in the hard mask layers 280 and 270, thereby exposing the backside of the substrate 110. After the etching process, the photoresist mask PM1 may be removed by suitable stripping or ashing process.

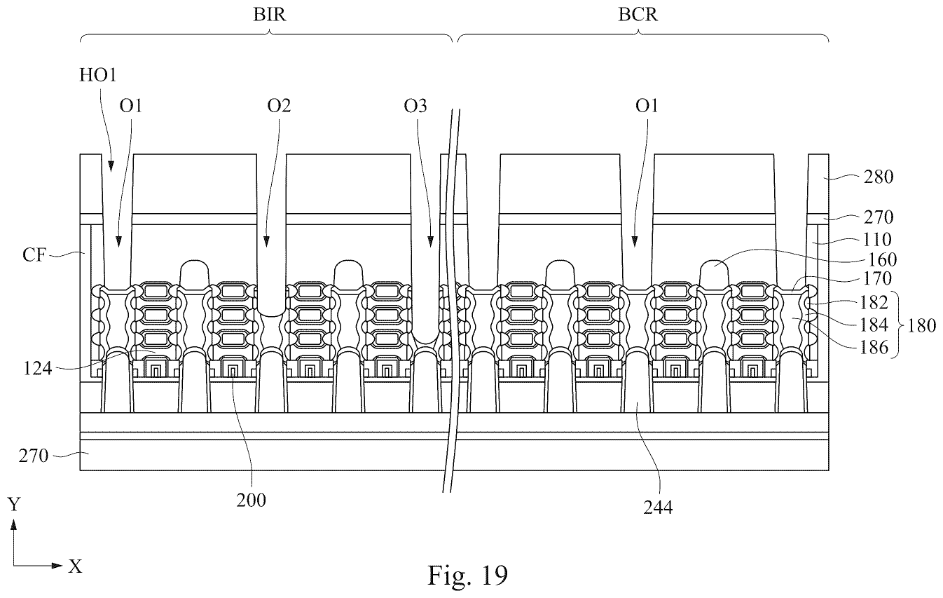

Reference is made to FIG. 19. Like the first to third etching processes in FIGS. 10-12, by applying the multiple masks (e.g., masks PM1-PM3 in FIGS. 11-12), a depth control backside process is performed to form openings with different etch depths on a same wafer. In some embodiments, one depth corresponds to one low end mask/one etch recipe. For example, bottoms of the openings O3 are lower than bottoms of the openings O2, and the bottoms of the openings O2 are lower than bottoms of the openings O1. Through the operations, the openings O1 may not expose backsides of the source/drain epitaxial structure 180, the openings O2 is laterally located between the bottommost ones of the nanosheets 124, and the opening O3 is laterally located between the second bottommost ones of the nanosheets 124. The multiple masks (e.g., masks PM1-PM3 in FIGS. 11-12 are controlled such that openings O1-O3 are etched in the region BIR of the substrate 110, and openings O1 are etched in the region BCR of the substrate 110. Other details of the formation of the openings O1-O3 are similar to those illustrated in FIGS. 10-12, and not repeated thereto.

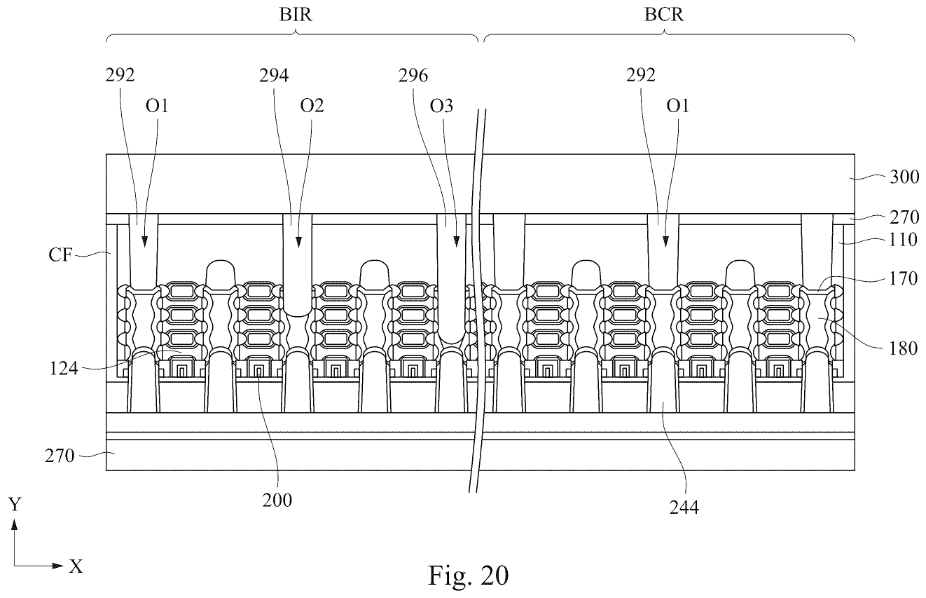

Reference is made to FIG. 20. Dielectric plugs 292-296 are formed in the openings O1-O3, respectively. The dielectric plugs 292-296 may be made of SiO₂, Si₃N₄, SiN, polyimide (PI), any other low-k dielectrics, the like, or the combination thereof. For example, the dielectric plugs 292-296 may include low-k dielectric materials having k values, for example, lower than about 4.0 or even 2.0. Formation of the dielectric plugs 292-296 includes depositing a dielectric layer over the hard mask layer 280 and into the openings O1-O3, followed by a planarization process (e.g., a CMP process). In the present embodiments, the CMP process also removes the hard mask layer 280. As shown in FIG. 20, after the planarization process, remaining portions of the dielectric layer forms the dielectric plugs 292, 294, and 296. The dielectric plug 292 is in contact with the bottom isolation layer 170 and spaced apart from the source/drain epitaxial structures 180 by the bottom isolation layer 170. The dielectric plug 294 is in contact with the source/drain epitaxial structures 180 and between the bottommost ones of the nanosheets 124. The dielectric plug 294 is in contact with the source/drain epitaxial structures 180 and between the second bottommost ones of the nanosheets 124. After the formation of the dielectric plugs 292-296, a hard mask layer 300 (e.g., an oxide hard mask) is redeposited on the hard mask layer 270 for the subsequent backside contact via process. According to the location of the openings O1-O3, the dielectric plugs 292-296 are formed in the region BIR of the substrate 110, and the dielectric plugs 292 are formed in the region BCR of the substrate 110. Other details of the formation of the dielectric plugs 292-296 and the hard mask layer 300 are similar to those illustrated in FIGS. 13-15, and not repeated thereto.

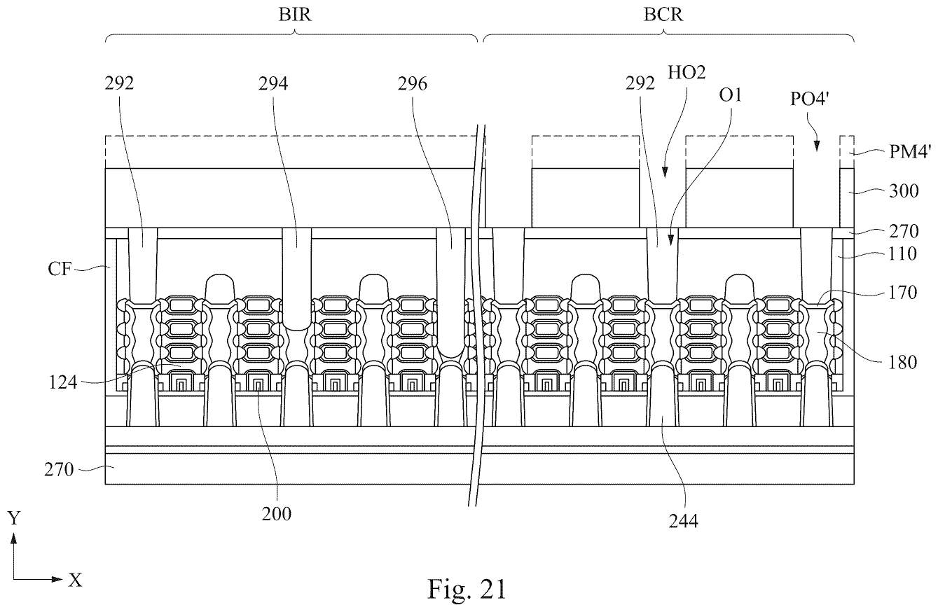

Reference is made to FIG. 21. A photoresist mask PM4′ may be formed over the hard mask layer 300. The photoresist mask PM4′ may cover the region BIR and have openings PO4′ in the region BCR. In some embodiments, the photoresist mask PM3 may include a photoresist formed by a photolithography process, in which a wavelength of the exposure light thereof is longer than a wavelength of the EUV light used for the high-resolution photoresist mask PM1 (referring to FIG. 18). An exemplary photolithography process may include processing steps of photoresist coating, soft baking, mask aligning, exposing, post-exposure baking, developing photoresist and hard baking.

Using the photoresist mask PM4′ as an etch mask, an etching process is performed to etch openings HO2 in the hard mask layers 300 and 270, thereby exposing backsides of the dielectric plugs 292 in the region BCR. After the etching process, the photoresist mask PM4′ may be removed by suitable stripping or ashing process.

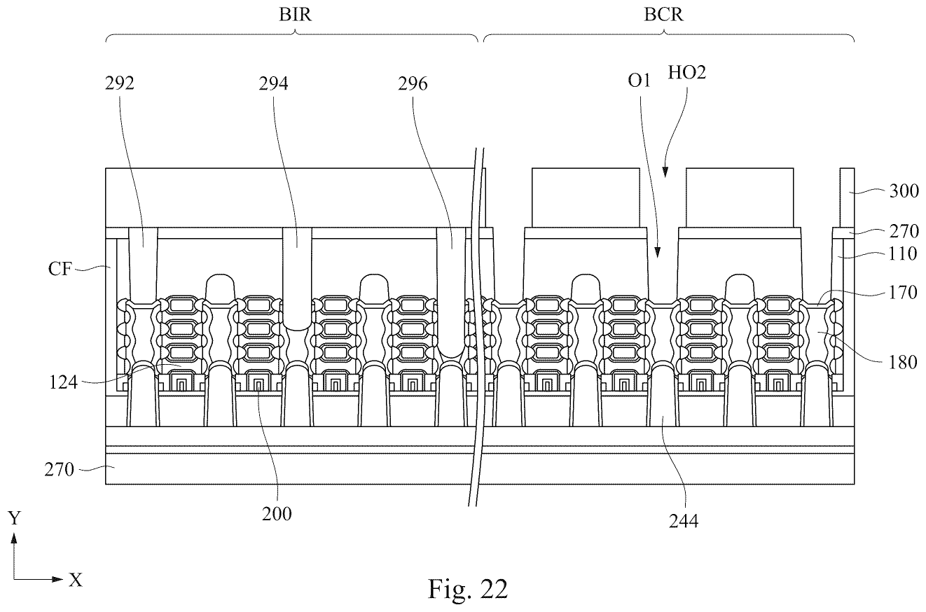

Reference is made to FIG. 22. With the presence of the hard mask layers 300 and 270, a selective etching process is performed to remove the dielectric plugs 292 in the region BCR from the openings O1 in the region BCR. For example, the selective etching process etches the dielectric plugs 292 at a fast etch rate than it etches the hard mask layer 300, the hard mask layer 270, and materials of the substrate 110, such that the dielectric plugs 292 can be removed from the openings O1. In some embodiments, the bottom isolation layer 170 may serve as a etch stop layer during the selective etching process, thereby protecting the underlying source/drain epitaxial structures 180 from being etched.

Reference is made to FIG. 23. Dielectric liners 312 may be formed on sidewalls of the openings O1 in the region BCR of the substrate 110. Formation of the dielectric liners may include conformally depositing a dielectric liner layer over the hard mask layer 270 and into the openings O1, and removing bottom portions of the dielectric liner layer to expose backsides of the source/drain epitaxial structures 180. The removal of the bottom portion of the dielectric liner layer may include a clean or etch process. Metal silicide regions MS may be formed on exposed top surfaces of the source/drain epitaxial structures 180 by using a silicidation process. Backside source/drain contacts 322 are formed in the openings O1 over the backsides of the source/drain epitaxial structures 180. A backside MLI structure 330 is formed over the backside source/drain contacts 322. Other details of the dielectric liners 312, the metal silicide regions MS, the backside source/drain contacts 322, and the backside MLI structure 330 are similar to those illustrated in FIG. 17, and thereto not repeated herein.

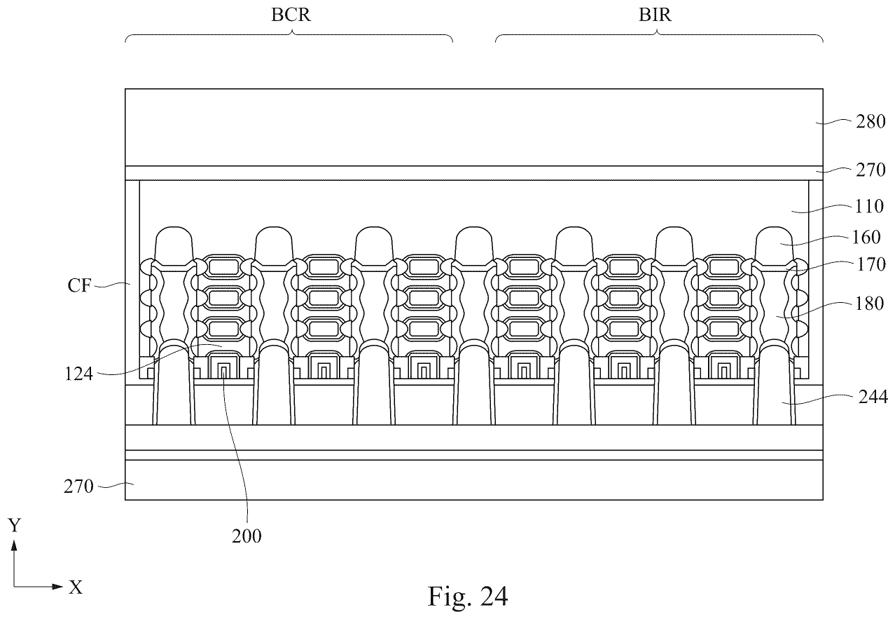

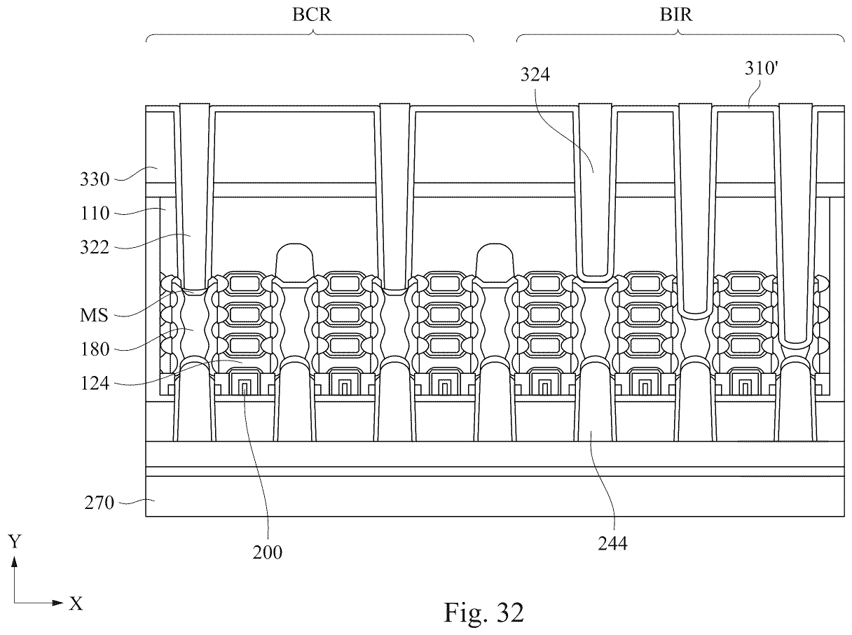

FIGS. 24-32 illustrate cross-sectional views of intermediate stages in the manufacture of a semiconductor device in accordance with some embodiments of the present disclosure. FIGS. 24-32 illustrates cross-sectional views of the semiconductor device taken along a same direction as the line B-B in FIG. 4A. The illustrated process in FIGS. 24-32 may be performed after the process in FIGS. 1-7, and applicable to manufacture the semiconductor device in FIG. 32. It is understood that additional steps may be provided before, during, and after the steps shown in FIGS. 24-32, and some of the steps described below can be replaced or eliminated for additional embodiments of the method. The order of the operations/processes may be interchangeable.

Reference is made to FIG. 24. The structure of FIG. 7 is bonded with a carrier substrate, and flipped upside down after bonding. A thinning process may be performed on a backside of the substrate 110, thereby reducing a thickness of the substrate 110. Subsequently, a bilayer hard mask layer including a hard mask layer 270 and a hard mask layer 280 is formed on the backside of the substrate 110. Other details are similar to those illustrated in FIG. 8, and thereto not repeated herein.

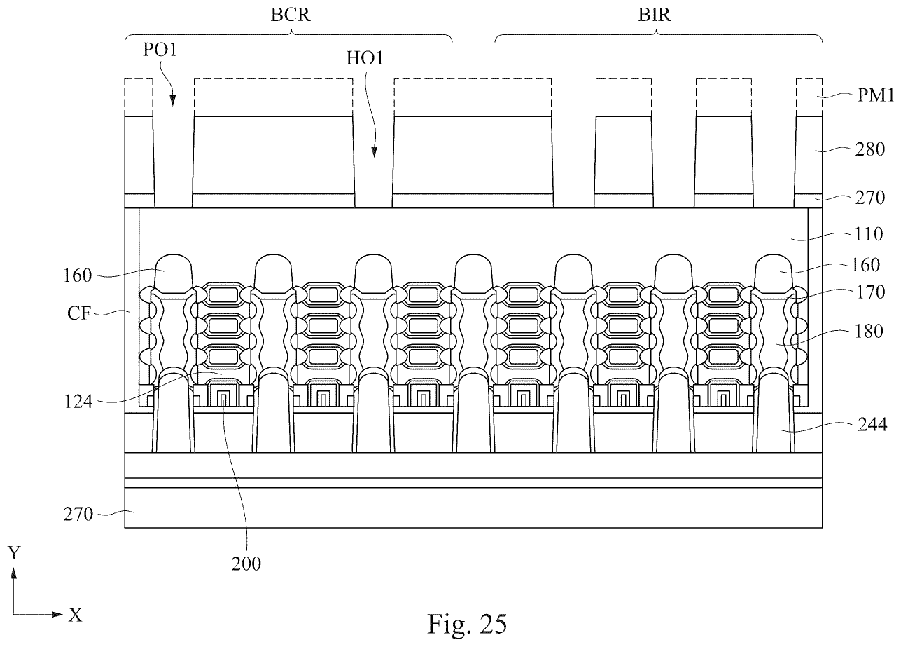

Reference is made to FIG. 25. A high-resolution photoresist mask PM1 may be formed over the hard mask layer 280. The high-resolution photoresist mask PM1 may have openings PO1 vertically aligned with the source/drain epitaxial structures 180 in the regions BCR and BIR. In some embodiments, the high-resolution photoresist mask PM1 may include a photoresist formed by a high-resolution photolithography process, such as extreme ultraviolet (EUV) photolithography process. An exemplary high-resolution photolithography process may include processing steps of photoresist coating, soft baking, mask aligning, exposing, post-exposure baking, developing photoresist and hard baking.

Using the high-resolution photoresist mask PM1 as an etch mask, an etching process is performed to etch openings HO1 in the hard mask layers 280 and 270, thereby exposing the backside of the substrate 110. After the etching process, the photoresist mask PM1 may be removed by suitable stripping or ashing process.

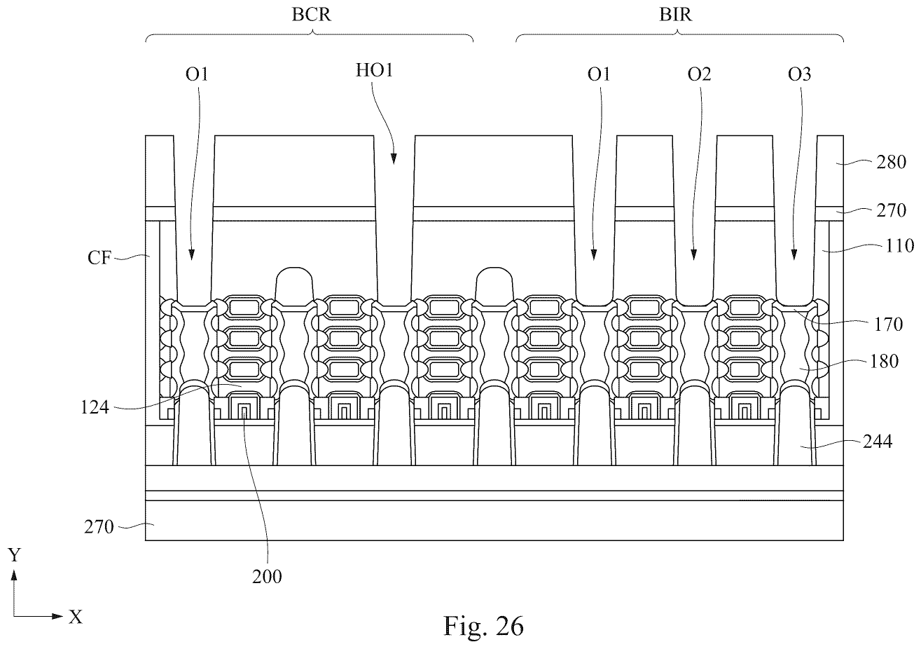

Reference is made to FIG. 26. Using the hard mask layer 280 as an etch mask, a first etching process is performed to etch openings O1 in the region BCR of the substrate 110 and etch openings O1-O3 in the region BIR of the substrate 110. The first etching process may remove the epitaxial features 160 and expose the bottom isolation layer 170. For example, the first etching process etches the epitaxial features 160 and the substrate 110 at a fast etch rate than it etches the bottom isolation layer 170, such that the bottom isolation layer 170 may serve as a etch stop layer and protect the underlying source/drain epitaxial structure 180 during the etching process.

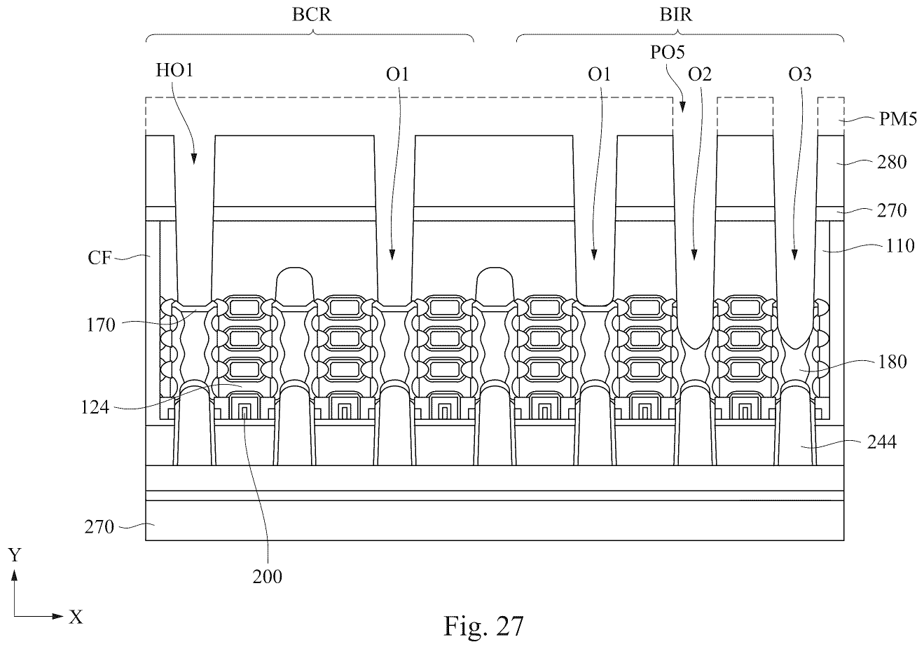

Reference is made to FIG. 27. A photoresist mask PM5 having openings PO5 may be formed over the hard mask layer 280. The photoresist mask PM5 may cover the openings O1 in the regions BCR and BIR and expose the openings O2-O3 in the region BIR by the openings PO5. In some embodiments, the photoresist mask PM5 may include a photoresist formed by a photolithography process, in which a wavelength of the exposure light thereof is longer than a wavelength of the EUV light used for the high-resolution photoresist mask PM1 (referring to FIG. 25). An exemplary photolithography process may include processing steps of photoresist coating, soft baking, mask aligning, exposing, post-exposure baking, developing photoresist and hard baking.

Using the photoresist mask PM5 as an etch mask, a third etching process may be performed to deepen the openings O2 and O3 in the region BIR. For example, after the third etching process, the openings O2 and O3 are laterally located between the bottommost ones of the nanosheets 124. After the third etching process, the photoresist mask PM5 may be removed by suitable stripping or ashing process.

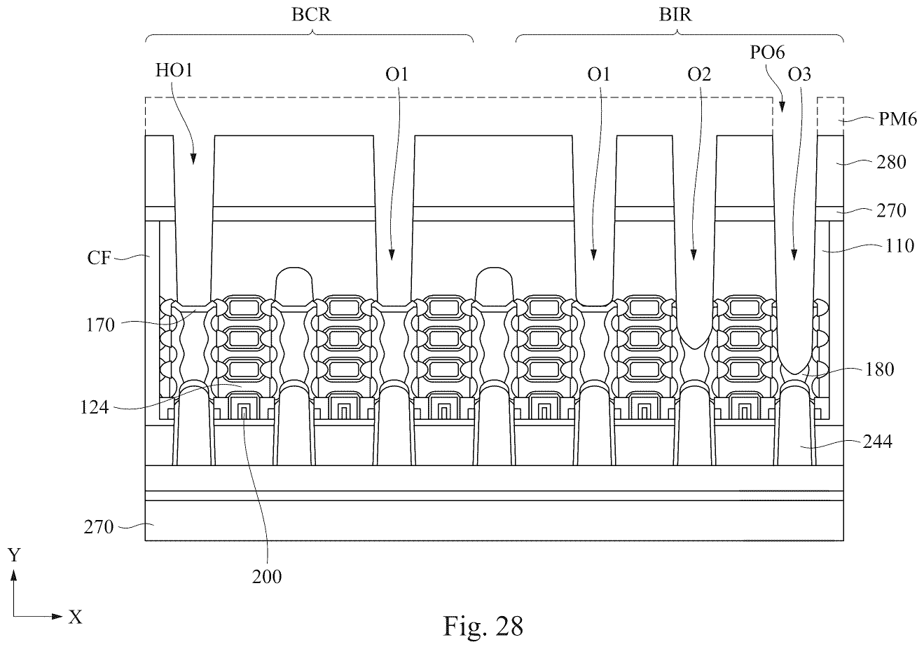

Reference is made to FIG. 28. A photoresist mask PM6 having openings PO6 may be formed over the hard mask layer 280. The photoresist mask PM6 may cover the openings O1 and O2 in the regions BCR and BIR and expose the openings O3 in the region BIR by the openings PO6. In some embodiments, the photoresist mask PM6 may include a photoresist formed by a photolithography process, in which a wavelength of the exposure light thereof is longer than a wavelength of the EUV light used for the high-resolution photoresist mask PM1 (referring to FIG. 25). An exemplary photolithography process may include processing steps of photoresist coating, soft baking, mask aligning, exposing, post-exposure baking, developing photoresist and hard baking.

Using the photoresist mask PM6 as an etch mask, a third etching process may be performed to deepen the opening O3 in the region BIR. For example, after the third etching process, the opening O3 is laterally located between the second bottommost ones of the nanosheets 124. After the third etching process, the photoresist mask PM6 may be removed by suitable stripping or ashing process.

The first to third etching processes in FIGS. 26-28 may use different etch recipes. For example, the first etching process in FIG. 26 uses a first gas etchant for removing the semiconductor materials in the substrate 110 and not substantially remove the bottom isolation layer 170. For example, the second etching process in FIG. 27 uses a second gas etchant for removing the bottom isolation layer 170 and a small amount of the semiconductor materials in the source/drain epitaxial structures 180. The third etching process in FIG. 28 uses a third gas etchant for removing the semiconductor materials in the source/drain epitaxial structures 180. The first to third gas etchant may be different from each other. In some other embodiments, one or more of the first to third etching processes may use two or more gas etchants, and the first to third etching processes may share some of the gas etchants at some stages. In some embodiments of the present disclosure, by applying the multiple masks (e.g., masks PM1, PM5, PM6), a depth control backside process is performed to form different etch depths on a same wafer. In some embodiments, one depth corresponds to one low end mask/one etch recipe. In some embodiments, one depth corresponds to one low end mask/one etch recipe. For example, a bottom of the opening O3 is lower than a bottom of the opening O2, and the bottom of the opening O2 is lower than a bottom of the opening O1.

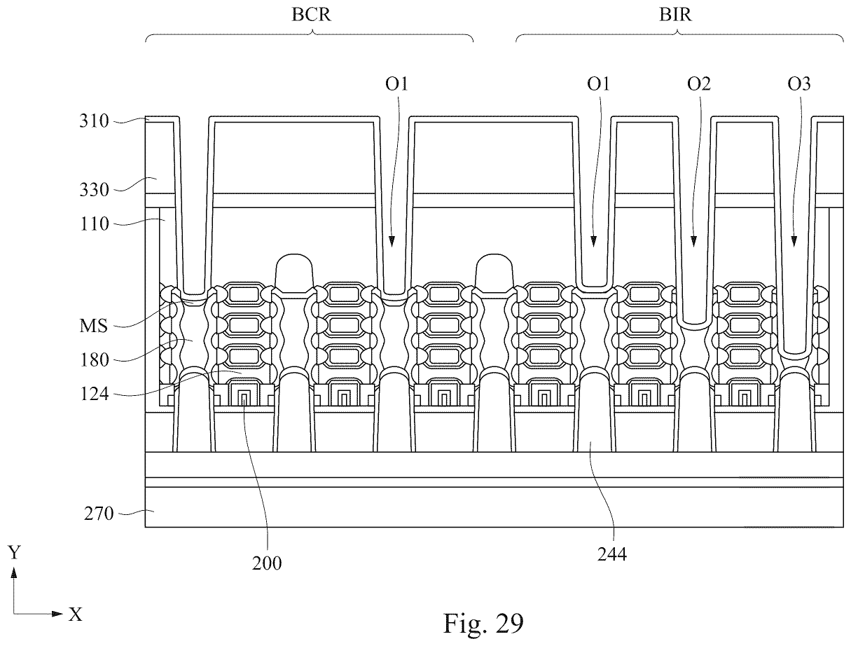

Reference is made to FIG. 29. A dielectric liner layer 310 is conformally deposited over the hard mask layer 280 and into the openings O1-O3. Material of the dielectric liner layer 310 may include silicon nitride, silicon oxynitride, silicon carbide, the like, or the combination thereof.

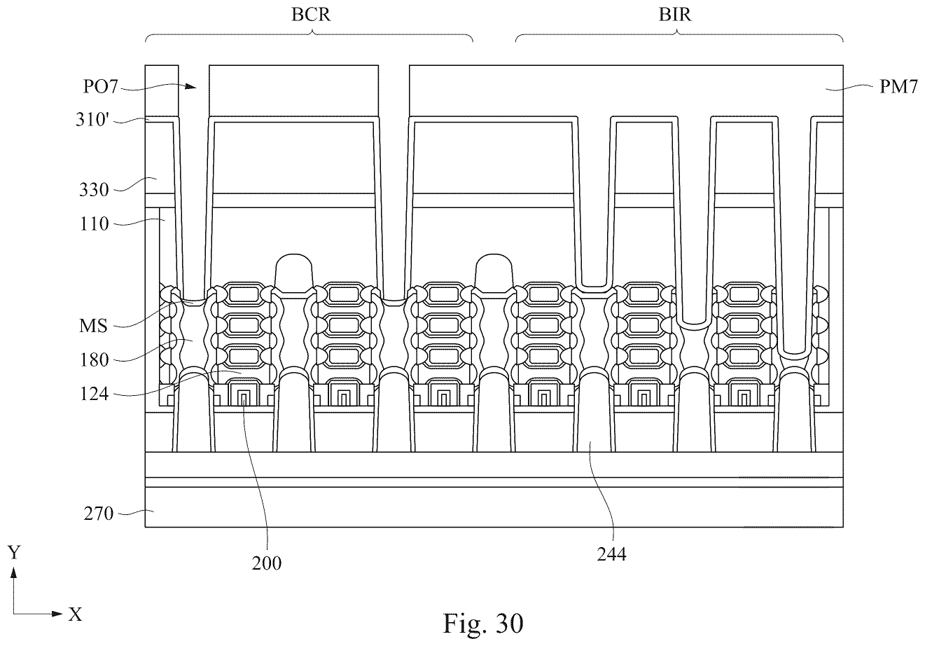

Reference is made to FIG. 30. A photoresist mask PM7 having openings PO7 may be formed over the dielectric liner layer 310. The photoresist mask PM7 may cover the openings O1-O3 in the region BIR and exposing the openings O1 in the region BCR by the openings PO7. In some embodiments, the photoresist mask PM7 may include a photoresist formed by a photolithography process, in which a wavelength of the exposure light thereof is longer than a wavelength of the EUV light used for the high-resolution photoresist mask PM1 (referring to FIG. 25). An exemplary photolithography process may include processing steps of photoresist coating, soft baking, mask aligning, exposing, post-exposure baking, developing photoresist and hard baking.

Using the photoresist mask PM6 as an etch mask, a liner removal process may be performed to remove bottom portions of the dielectric liner layers 310 (referred to FIG. 29) in the openings O1 in the region BCR to expose backsides of the source/drain epitaxial structures 180. The liner removal process may be a wet clean or etch process.

For example, after the liner removal process, the opening O1 in the region BCR is extended through the dielectric liner layer 310 (referred to FIG. 29), thereby exposing backsides of the source/drain epitaxial structures 180. The dielectric liner layer have the opening O1 therein may be referred to as a dielectric liner layer 310′ hereinafter. After the liner removal process, the photoresist mask PM6 may be removed by suitable stripping or ashing process.

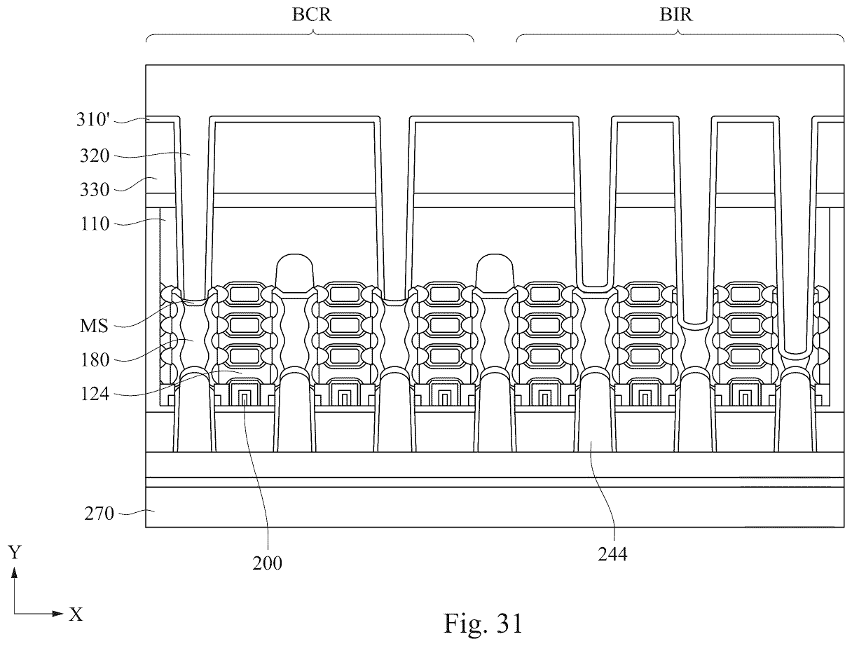

Reference is made to FIG. 31. A metal material 320 is deposited into the openings O1-O3 in both the region BCR and BIR. The metal material 320 may include W, Ru, Co, Cu, Ti, TiN, Ta, TaN, Mo, Ni, Pt, Ir, Rh, the like or combinations thereof. The metal materials are deposited to fill the openings O1-O3 by using suitable deposition techniques (e.g., CVD, PVD, ALD, the like or combinations thereof). The metal material 320 may include a single metal material or multiple metal material layers.

In some embodiments, prior to depositing the metal material 320, metal silicide regions MS may be formed on exposed top surfaces of the source/drain epitaxial structures 180 by using a silicidation process. Silicidation may be formed by blanket depositing a metal layer over the exposed source/drain epitaxial structures 180, annealing the metal layer such that the metal layer reacts with silicon (and germanium if present) in the source/drain epitaxial structures 180 to form the metal silicide regions MS, and thereafter removing the non-reacted metal layer. In some embodiments, the metal layer used in the silicidation process includes nickel, cobalt, titanium, tantalum, platinum, tungsten, other noble metals, other refractory metals, rare earth metals or their alloys. Thus, metal silicide regions MS may be between the backside source/drain contacts 322 and the source/drain epitaxial structures 180.

Reference is made to FIG. 32. A planarization process (e.g., a CMP process) can be performed to remove an excess portion of the metal material 320 outside the openings O1-O3, while leaving remaining portions of the metal material 320 in the openings O1-O3 to serve as the backside source/drain contacts 322 and metal features 324, respectively.

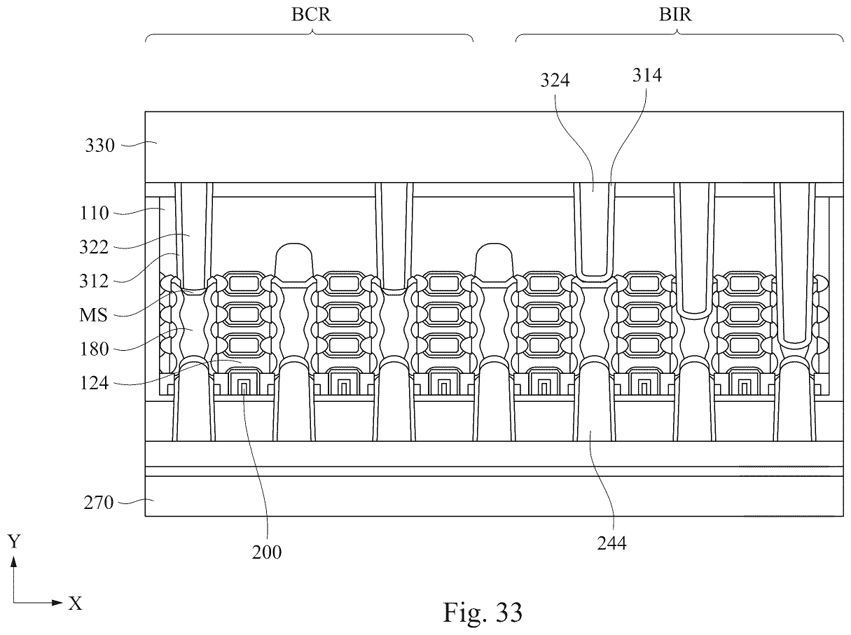

The planarization process (e.g., a CMP process) may continue to remove an excess portion of the dielectric liner layer 310′ over the hard mask layer 280 and outside the openings O1-O3. Remaining portions of the dielectric liner layer 310′ in the openings O1 in the region BCR serve as dielectric liners 312, and remaining portions of the dielectric liner layer 310′ in the openings O1 in the region BIR serve as dielectric liners 314. The dielectric liners 312 have openings to allow the connection between the backside source/drain contacts 322 and the underlying source/drain epitaxial structures 180, respectively. The dielectric liners 314 space the metal features 324 from the underlying source/drain epitaxial structures 180, respectively. A combination of the dielectric liner 314 and the metal feature 324 thereon may be referred to as an isolation plug in com embodiments. In some examples, the isolation plug may cut/block the sheets/channels from backside of the substrate. The CMP process may further remove the hard mask layer 280 from the hard mask layer 270. Afterwards, a backside MLI structure 330 is formed over the backside source/drain contacts 322 and the metal features 324. The resulted structure is shown in FIG. 33. Other details of the present embodiments are similar to those illustrated above, and thereto not repeated herein.

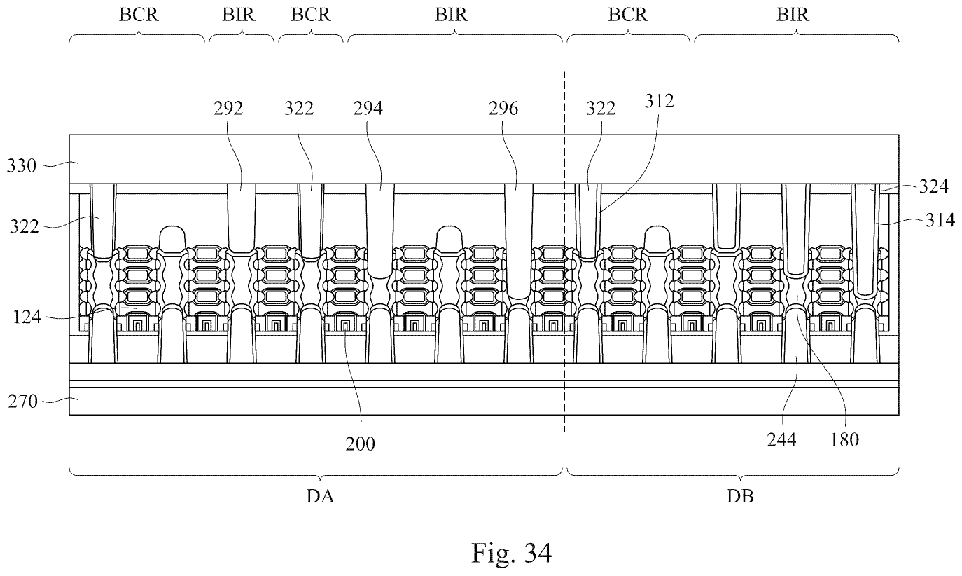

FIG. 34 is a cross-sectional view of a semiconductor device in accordance with some embodiments of the present disclosure. The semiconductor device in the region DA may be formed by the manufacture process of FIGS. 1-17 or the manufacture process of FIGS. 18-23, and the semiconductor device in the region DB may be formed by the manufacture process of FIGS. 24-33. Other details of the present embodiments are similar to those illustrated above, and thereto not repeated herein.

Based on the above discussions, it can be seen that the present disclosure offers advantages. It is understood, however, that other embodiments may offer additional advantages, and not all advantages are necessarily disclosed herein, and that no particular advantage is required for all embodiments. One advantage is that a depth control backside process is developed to form backside dielectric plugs, which cut sheets from backside of the substrate, thereby achieving flexible number of nanosheets in multi-gate devices. Another advantage is that devices with a higher sheet number and devices with a lower sheet number can be formed by a same process, in which the higher sheet number is advantageous for larger DC performance device and lower channel resistance, while the lower sheet number is advantageous for lower capacitance, higher speed and less power consumption. Still another advantage is that with the scheme of N sheet, the backside dielectric plugs can block the last few sheets from backside, remain only N−1, N−2, N−3 number of sheets, so on so forth, in which N can be any real number.

According to some embodiments of the present disclosure, a method includes forming a plurality of channel layers vertically stacked over a semiconductor substrate; forming a gate structure surrounding the channel layers; forming a first source/drain epitaxial structure on a first side of the channel layers; etching a first opening at least in the semiconductor substrate and the first source/drain epitaxial structure expose a backside of the first source/drain epitaxial structure; and forming an isolation plug in the first opening, wherein the isolation plug is at least laterally aligned with a bottommost one of the channel layers.

According to some embodiments of the present disclosure, a method includes forming a plurality of first channel layers vertically stacked over a semiconductor substrate and a plurality of second channel layers vertically stacked over the semiconductor substrate; forming a first source/drain epitaxial structure on a side of the first channel layers; forming a second source/drain epitaxial structure on a side of the second channel layers; forming a first patterned mask over a backside of the semiconductor substrate; with the first patterned mask in place, etching a first opening and a second opening in the semiconductor substrate, wherein the first and second openings are respectively vertically aligned with the first and second source/drain epitaxial structures; deepening the second opening, such that a depth of the second opening is greater than a depth of the first opening; and forming a first isolation plug and a second isolation plug in the first opening and the second opening, respectively.

According to some embodiments of the present disclosure, a semiconductor device includes first channel layers, second channel layers, a first gate structure, a second gate structure, a first source/drain epitaxial structure, a second source/drain epitaxial structure, a first isolation plug, and a second isolation plug. The first channel layers are vertically stacked over a semiconductor substrate. The second channel layers are vertically stacked over the semiconductor substrate. The first gate structure surrounds the first channel layers. The second gate structure surrounds the second channel layers. The first source/drain epitaxial structure is on a side of the first channel layers. The second source/drain epitaxial structure is on a side of the second channel layers. The first isolation plug is over a backside of the first source/drain epitaxial structure. The second isolation plug is over a backside of the second source/drain epitaxial structure. A height of the first isolation plug is greater than a height of the second isolation plug.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method, comprising:
forming a plurality of channel layers vertically stacked over a semiconductor substrate;
forming a gate structure surrounding the channel layers;
forming a first source/drain epitaxial structure on a first side of the channel layers;
etching a first opening at least in the semiconductor substrate and the first source/drain epitaxial structure expose a backside of the first source/drain epitaxial structure; and
forming an isolation plug in the first opening, wherein the isolation plug is at least laterally aligned with a bottommost one of the channel layers.

2. The method of claim 1, wherein the isolation plug is further laterally aligned with a second bottommost one of the channel layers.

3. The method of claim 1, wherein forming the isolation plug comprises depositing a dielectric fill material into the first opening.

4. The method of claim 1, wherein forming the isolation plug comprises:
depositing a dielectric liner layer into the first opening; and
forming a metal feature in the first opening and over the dielectric liner, wherein the dielectric liner layer spaces the metal feature from the first source/drain epitaxial structure.

5. The method of claim 1, wherein forming the isolation plug is performed such that the isolation plug is spaced apart from the channel layers by a portion of the first source/drain epitaxial structure.

6. The method of claim 1, further comprising:
prior to etching the first opening, forming a frontside source/drain contact on a frontside of the first source/drain epitaxial structure.

7. The method of claim 1, further comprising:
forming a second source/drain epitaxial structure on a second side of the channel layers; and
etching a second opening in the semiconductor substrate to expose a backside of the second source/drain epitaxial structure; and
forming a backside source/drain contact in the second opening in the semiconductor substrate and on the backside of the second source/drain epitaxial structure.

8. The method of claim 7, wherein a depth of the first opening is greater than a depth of the second opening.

9. The method of claim 7, further comprising:
forming a contact liner in the second opening and exposing the backside of the second source/drain epitaxial structure, wherein the contact liner comprises a same dielectric material as a dielectric liner layer of the isolation plug.

10. The method of claim 1, further comprising:
forming a bottom isolation layer over the semiconductor substrate, wherein the first source/drain epitaxial structure is formed on the bottom isolation layer, and etching the first opening is performed such that the first opening extends through the bottom isolation layer.

11. A method, comprising:
forming a plurality of first channel layers vertically stacked over a semiconductor substrate and a plurality of second channel layers vertically stacked over the semiconductor substrate;
forming a first source/drain epitaxial structure on a side of the first channel layers;
forming a second source/drain epitaxial structure on a side of the second channel layers;
forming a first patterned mask over a backside of the semiconductor substrate;
with the first patterned mask in place, etching a first opening and a second opening in the semiconductor substrate, wherein the first and second openings are respectively vertically aligned with the first and second source/drain epitaxial structures;
deepening the second opening, such that a depth of the second opening is greater than a depth of the first opening; and
forming a first isolation plug and a second isolation plug in the first opening and the second opening, respectively.

12. The method of claim 11, wherein deepening the second opening comprises:
forming a second patterned mask over a backside of the semiconductor substrate, wherein the second patterned mask covers the first opening and uncovers the second opening; and
with the second patterned mask in place, etching the second opening into the second source/drain epitaxial structure.

13. The method of claim 12, wherein the first patterned mask is formed by a first lithography process, the second patterned mask is formed by a second lithography process, and an exposure light of the second lithography process has a wavelength longer than an exposure light of the first lithography process.

14. The method of claim 11, wherein forming the first isolation plug and the second isolation plug is performed such that a bottom surface of the second isolation plug is lower than a bottom surface of the first isolation plug.

15. The method of claim 11, further comprising:
forming a backside interconnect structure over a top surface of the first isolation plug and a top surface of the second isolation plug.

16. A semiconductor device, comprising:
a plurality of first channel layers vertically stacked over a semiconductor substrate;
a plurality of second channel layers vertically stacked over the semiconductor substrate;
a first gate structure surrounding the first channel layers;
a second gate structure surrounding the second channel layers;
a first source/drain epitaxial structure on a side of the first channel layers a second source/drain epitaxial structure on a side of the second channel layers;
a first isolation plug over a backside of the first source/drain epitaxial structure; and
a second isolation plug over a backside of the second source/drain epitaxial structure, wherein a height of the first isolation plug is greater than a height of the second isolation plug.

17. The semiconductor device of claim 16, wherein the second isolation plug is in contact with the second source/drain epitaxial structure.

18. The semiconductor device of claim 16, further comprising:
a plurality of third channel layers vertically stacked over the semiconductor substrate;
a third gate structure surrounding the third channel layers;
a third source/drain epitaxial structure on a side of the second channel layers; and
a backside contact on a backside of the third source/drain epitaxial structure, wherein the height of the first isolation plug is greater than a height of the backside contact.

19. The semiconductor device of claim 16, wherein each of the first and second isolation plugs comprises a dielectric fill material.

20. The semiconductor device of claim 16, wherein each of the first and second isolation plugs comprises:
a metal feature; and
a dielectric liner surrounding the metal feature.
